(19) United States
(12) Patent Application Publication
(10) Pub. No.: US 2026/0371878 A1
(43) Pub. Date: Nov. 19, 2026

(54) DISPLAY PANEL AND DISPLAY APPARATUS

(71) Applicant: Xiamen Tianma Optoelectronics Co., Ltd., Xiamen (CN)

(72) Inventors: Wen HUANG, Xiamen (CN); Zhaokeng CAO, Xiamen (CN)

(21) Appl. No.: 19/725,102

(22) Filed: Jun. 30, 2026

(30) Foreign Application Priority Data
Dec. 31, 2025 (CN) 202512058628.8

(51) Int. Cl. H10K 59/131; G09G 3/3233; H10K 59/35

(52) U.S. Cl. CPC H10K 59/131; G09G 3/3233; H10K 59/353; G09G 2300/0452; G09G 2300/0842; G09G 2310/0286; G09G 2310/08; G09G 2330/02

(57) ABSTRACT

A display panel and a display apparatus. The display panel includes a display area and a non-display area. The display area includes sub-pixels and data lines extending along a first direction, data lines includes first data lines and second data lines adjacent to each other, one first data line connects two sub-pixels with different colors, and one second data line connects two sub-pixels with different colors. The non-display area includes data leads, power-supply leads and reference leads, and the data leads include first data leads and second data leads. The first data lead is connected to first data line, and the second data lead is connected to second data line. The power-supply lead and/or the reference lead are arranged between the first data lead and the second data lead adjacent to each other. The present disclosure can improve signal coupling crosstalk between adjacent data leads.

### CROSS-REFERENCE TO RELATED APPLICATION

The present application claims priority to Chinese Patent Application No. 202512058628.8, filed on Dec. 31, 2025, the content of which is incorporated herein by reference in its entirety.

### TECHNICAL FIELD

The present disclosure relates to the technical field of display, and in particular, to a display panel and a display apparatus.

### BACKGROUND ART

Multiple data lines are arranged in a display area of a display panel. A data voltage is provided for pixel circuits through the data lines to control light-emitting devices to display with different gray scale brightness. Data leads are arranged in a non-display area of the display panel, and data lines are connected to a display driving chip through the data leads. Multiple data leads are led out from boundary positions of the display area and the non-display area and then gradually converge to form a sector-shaped arrangement. In a lead area of the sector-shaped arrangement, a distance between two adjacent data leads is reduced, and a data voltage jump frequency on the data leads is high, thereby resulting in serious signal coupling crosstalk between adjacent data leads, affecting accuracy of transmitting data voltage, and further affecting display quality.

### SUMMARY

An aspect of the present disclosure provides a display panel. The display panel includes a display area and a non-display area. The display area includes sub-pixels and data lines extending along a first direction. The data lines include first data lines and second data lines, one of the first data lines is adjacent to one of the second data lines, one of the first data lines is connected to two of the sub-pixels with different colors, and one of the second data lines is connected to two sub-pixels with different colors. The non-display area includes data leads, power-supply leads, and reference leads, the data leads comprise first data leads and second data leads, the first data leads are connected to one of the first data lines, and the second data leads are connected to the second data lines. One of the power-supply leads and/or one of the reference leads are arranged between one of the first data leads and one of the second data leads that are adjacent to each other.

Another aspect of the present disclosure provides a display apparatus. The display apparatus includes a display panel. The display panel includes a display area and a non-display area. The display area includes sub-pixels and data lines extending along a first direction. The data lines include first data lines and second data lines, one of the first data lines is adjacent to one of the second data lines, one of the first data lines is connected to two of the sub-pixels with different colors, and one of the second data lines is connected to two sub-pixels with different colors. The non-display area includes data leads, power-supply leads, and reference leads, the data leads comprise first data leads and second data leads, the first data leads are connected to one of the first data lines, and the second data leads are connected to the second data lines. One of the power-supply leads and/or one of the reference leads are arranged between one of the first data leads and one of the second data leads that are adjacent to each other.

### BRIEF DESCRIPTION OF DRAWINGS

In order to more clearly illustrate the embodiments of the present disclosure or the technical solutions in the related art, following briefly describes the accompanying drawings that need to be used in the embodiments or the related art description. Obviously, the accompanying drawings in following description are some embodiments of the present disclosure. For those skilled in the art, any other accompanying drawing may be obtained according to these accompanying drawings.

FIG. 1 is a schematic diagram of a display panel according to an embodiment of the present disclosure;

FIG. 2 is a schematic diagram of a display panel according to an embodiment of the present disclosure;

FIG. 3 is a partial schematic diagram of a display panel according to an embodiment of the present disclosure;

FIG. 4 is a signal timing sequence diagram according to an embodiment of the present disclosure;

FIG. 5 is a partial schematic diagram of a display panel according to an embodiment of the present disclosure;

FIG. 6A is a timing sequence diagram according to an embodiment of the present disclosure;

FIG. 6B is a timing sequence diagram according to an embodiment of the present disclosure;

FIG. 6C is a timing sequence diagram according to an embodiment of the present disclosure;

FIG. 7 is a schematic diagram of a display panel according to an embodiment of the present disclosure;

FIG. 8A is a schematic diagram of a display panel according to an embodiment of the present disclosure;

FIG. 8B is a schematic cross-sectional view of a display panel according to an embodiment of the present disclosure;

FIG. 9 is a schematic diagram of a display panel according to an embodiment of the present disclosure;

FIG. 10 is a schematic diagram of a display panel according to an embodiment of the present disclosure;

FIG. 11 is a schematic diagram of a display panel according to an embodiment of the present disclosure;

FIG. 12 is a schematic diagram of a display panel according to an embodiment of the present disclosure;

FIG. 13 is a schematic diagram of a display panel according to an embodiment of the present disclosure;

FIG. 14 is a schematic diagram of a display panel according to an embodiment of the present disclosure;

FIG. 15 is a schematic diagram of a display panel according to an embodiment of the present disclosure;

FIG. 16 is a schematic diagram of a display panel according to an embodiment of the present disclosure;

FIG. 17 is a schematic diagram of a display panel according to an embodiment of the present disclosure;

FIG. 18 is a schematic diagram of a display panel according to an embodiment of the present disclosure;

FIG. 19 is a schematic diagram of a display panel according to an embodiment of the present disclosure;

FIG. 20 is a schematic diagram of a display panel according to an embodiment of the present disclosure;

FIG. 21 is a schematic diagram of a display panel according to an embodiment of the present disclosure; and

FIG. 22 is a schematic diagram of a display apparatus according to an embodiment of the present disclosure.

### DETAILED DESCRIPTION

In order to more clearly illustrate objectives, technical solutions, and advantages of the embodiments of the present disclosure, the technical solutions in the embodiments of the present disclosure are clearly and completely described in details with reference to the accompanying drawings. The described embodiments are merely part of the embodiments of the present disclosure rather than all of the embodiments. All other embodiments obtained by those skilled in the art based on the embodiments of the present disclosure shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

In the related art, multiple data leads are arranged in the non-display area of the display panel, the distance between two adjacent data leads is relatively short, and the data voltages on the data leads are switched at a high frequency, so that the coupling capacitance between the adjacent data leads is large, the signals on the adjacent data leads interfere with each other, thereby affecting the display quality. Therefore, embodiments of the present disclosure provide a display panel, in which an arrangement manner of fan-out leads in a non-display area is designed, a power-supply lead and/or a reference lead are arranged between two adjacent data leads, and during the display period, the power-supply lead and/or the reference lead play a role of signal shielding between two adjacent data leads, thereby reducing signal crosstalk between adjacent data leads, and thus improving accuracy of data voltage transmission on the data leads and improving display quality. Further, in some embodiments of the present disclosure, the arrangement manner of the signal lines in the display area is designed in cooperation with the arrangement manner of the leads in the non-display area, so that signal crosstalk between adjacent data leads in the non-display area can be improved, and a voltage drop of signal transmission in the display area can be reduced, thereby further improving display quality. Further, the design of wiring signal leads in the non-display area is applied in the DGLD (Dual Gate Line Driving) technology, which can improve the display quality while reducing the manufacturing cost. The above shows a main technical concept of the embodiments of the present disclosure, and the technical concept of the present disclosure will be illustrated below by following embodiments.

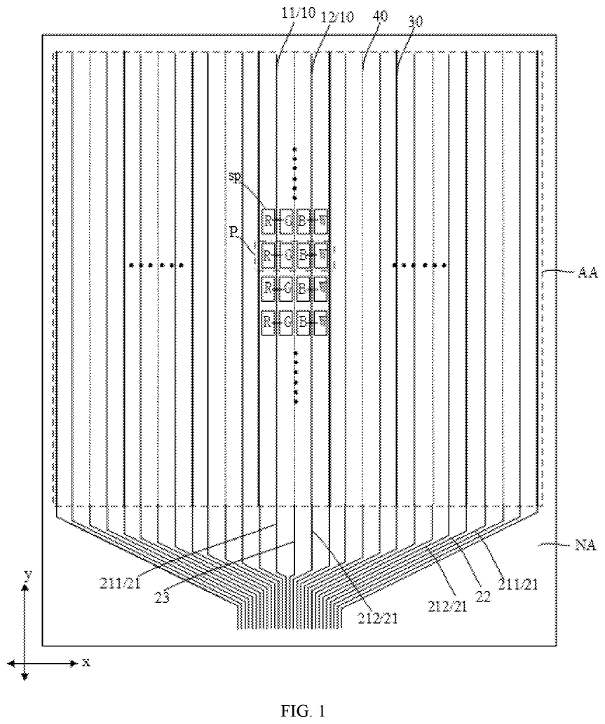

FIG. 1 is a schematic diagram of a display panel according to an embodiment of the present disclosure. As shown in FIG. 1, the display panel includes a display area AA and a non-display area NA; and the display area AA includes multiple sub-pixels sp, and multiple data lines 10, power-supply lines 30 and reference signal lines 40 that extend along the first direction y. Multiple signal lines in the display area AA are arranged along a second direction x, and the second direction x intersects the first direction y. In order to distinguish the signal lines in the display area AA, FIG. 1 shows that the data lines 10 are thin lines, the power-supply lines 30 are thick lines, and the reference signal lines 40 are dotted lines.

The data lines 10 include first data lines 11 and second data lines 12, one first data line 11 is adjacent to one second data line 12. The expression “one first data line 11 is adjacent to one second data line 12 means that no data line 10 for transmitting data voltage is provided between the first data line 11 and the second data line 12, while signal lines for transmitting other signals may be provided between the first data line 11 and the second data line 12. One first data line 11 is connected to two sub-pixels sp with different colors, and one second data line 12 is connected to two sub-pixels sp with different colors. FIG. 1 only illustrates the arrangement of the sub-pixels sp at a local position in the display area AA, and the schematic sub-pixels sp include red sub-pixels R, green sub-pixels G, blue sub-pixels B and white sub-pixels W, the first data line 11 connects the red sub-pixel R and the green sub-pixel G, and the second data line 12 connects the blue sub-pixel B and the white sub-pixel W. The sub-pixel includes a light-emitting device and a pixel circuit. The light-emitting device may be, for example, an organic light-emitting diode (OLED) device.

The non-display area NA includes data leads 21, power-supply leads 22, and reference leads 23. The data leads 21 include a first data lead 211 and a second data lead 212. The first data lead 211 is connected to the first data line 11, and the second data lead 212 is connected to the second data line 12. The power-supply lead 22 transmits a constant voltage signal required by the power-supply line 30, the reference lead 23 transmits the signal required by the reference signal line 40, and the reference lead 23 transmits a constant voltage signal in at least part of the sequence period for displaying one frame.

In FIG. 1, a power-supply lead 22 is provided between some adjacent first data leads 211 and second data leads 212, and a reference lead 23 is provided between some adjacent first data leads 211 and second data leads 212.

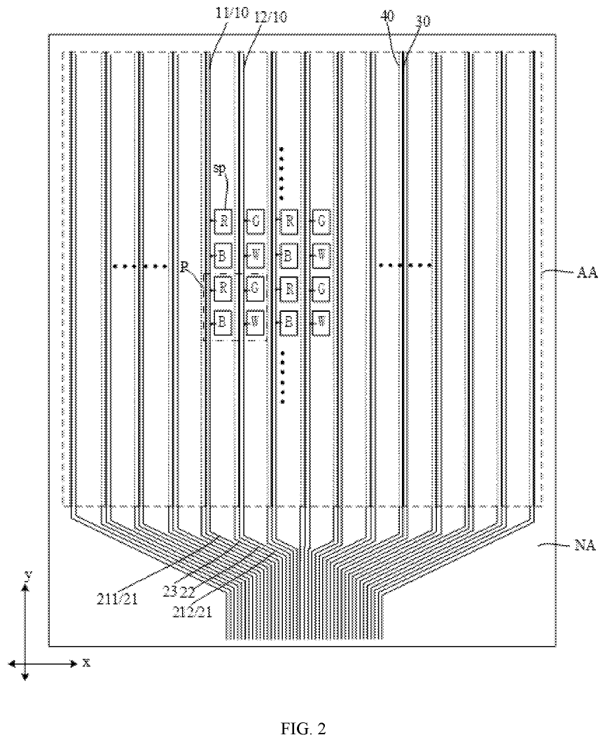

FIG. 2 is a schematic diagram of a display panel according to an embodiment of the present disclosure. As shown in FIG. 2, the display panel includes a display area AA and a non-display area NA. The display area AA includes multiple sub-pixels sp, and multiple data lines 10, power-supply lines 30 and reference signal lines 40 that extend along the first direction y. In order to distinguish the signal lines in the display area AA, FIG. 1 shows that the data lines 10 are thin lines, the power-supply lines 30 are thick lines, and the reference signal lines 40 are dotted lines. One first data line 11 connects two sub-pixels sp with different colors, and one second data line 12 connects two sub-pixels sp with different colors. For example, the first data line 11 is connected to the red sub-pixel R and the blue sub-pixel B, and the second data line 12 is connected to the green sub-pixel G and the white sub-pixel W. The non-display area NA is provided with a data lead 21, a power-supply lead 22 and a reference lead 23. The data lead 21 includes a first data lead 211 and a second data lead 212 The first data lead 211 is connected to the first data line 11, and the second data lead 212 is connected to the second data line 12. A power-supply lead 22 and a reference lead 23 are disposed between the first data lead 211 and second data lead 212 that are adjacent to each other.

In some embodiments, a first data lead 211, a second data lead 212, a power-supply lead 22 and a reference lead 23 are arranged in the non-display area NA, the first data lead 211 and the second data lead 212 respectively transmit a data voltage, the power-supply lead 22 transmits a constant voltage signal, and the reference lead 23 transmits a constant voltage signal in at least part of a sequence period for displaying one frame. The first data lead 211 is connected to a first data line 11 located in the display area AA, the second data lead 212 is connected to a second data line 12 located in the display area AA, the first data line 11 and the second data line 12 are respectively connected to two sub-pixels sp with different colors, and the first data line 11 and the second data line 12 are adjacent data lines 10. In addition, a power-supply lead 22 and/or a reference lead 23 are disposed between adjacent first data leads 211 and second data leads 212 in the non-display area NA, and during the display period, the power-supply lead 22 and/or the reference lead 23 play a role of shielding signals between the adjacent first data leads 211 and second data leads 212, thereby reducing signal crosstalk between the first data leads 211 and second data leads 212 that transmit high-frequency data voltages, improving accuracy of data voltage transmission on the data leads 21, and improving display quality.

In a display panel in the related art, a single gate line driving (SGLD) technology is generally used, that is, one sub-pixel row is driven by one gate line. SGLD OLED TVs have been continuously researched and developed. Considering the problem of reducing the manufacturing cost, a Dual Gate Line Driving technology (i.e., DGLD) has been further developed. In the DGLD technology, two gate lines are used to drive one sub-pixel row, and one data line is arranged to connect two sub-pixels with different colors in a same sub-pixel row. Two gate lines are cooperated with multiple data lines, so as to realize that the data voltage can be alternately controlled to be written into multiple sub-pixels in one sub-pixel row through the two gate lines within the row driving period, and the sub-pixel row is driven. After the DGLD technology is adopted, the number of data lines arranged in the display panel is halved, so that the number of data leads arranged in the non-display area can be reduced, the lower frame can be narrowed, the number of data terminals of the display driving chip can be reduced, and the manufacturing cost is reduced. The DGLD OLED will become a development trend for a large-size panel. At present, some technical problems appears in the development of DGLD OLED TV. It has been found through research that under a same resolution, the charging time of each row of sub-pixels in the DGLD technology is reduced by ⅓ compared with that of the traditional SGLD architecture, thereby resulting in higher frequency of data line transmission signals, and two columns of sub-pixels are more likely to interfere with each other and cause poor display. Meanwhile, the overall uniformity of the power-supply line transmission signal in the large-size panel is reduced due to the increase of the panel size. It can be seen that the problem of signal crosstalk and power-supply voltage uniformity between two adjacent columns of sub-pixels in the DGLD technology is extremely urgent.

In order to solve the problem encountered in a development process of DGLD OLED TV, considering that the crosstalk between two columns of sub-pixels is generally caused by a high frequency of change of the data signal on the data line and a short distance between the adjacent data leads in the non-display area. By improving signal coupling crosstalk between adjacent data leads, the display defects can be improved.

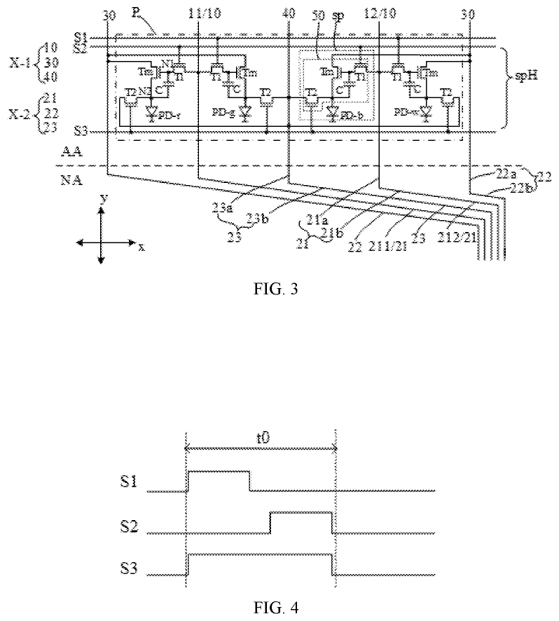

FIG. 3 is a partial schematic diagram of a display panel according to an embodiment of the present disclosure. The four sub-pixels sp in the display area AA are illustrated in FIG. 3, the connection manner of the data lines 10 and the sub-pixels sp in the display area AA in FIG. 3 is the same as that in some embodiments shown in FIG. 1, which illustrates a red light-emitting device PD-r, a green light-emitting device PD-g, a blue light-emitting device PD-b and a white light-emitting device PD-w, the first data line 11 is connected to the pixel circuits 50 corresponding to the red light-emitting device PD-r and the green light-emitting device PD-g, and the second data line 12 is connected to the pixel circuits 50 corresponding to the blue light-emitting device PD-b and the white light-emitting device PD-w. Multiple sub-pixels sp in the display area AA are arranged in a sub-pixel row spH in the second direction x. FIG. 3 shows four sub-pixels sp in one sub-pixel row spH. A first scan line S1, a second scan line S2, and a third scan line S3 that extend in the second direction x are arranged in the display area AA. One of the first switch transistor T1 of the odd-numbered sub-pixel sp and the first switch transistor T1 of the even-numbered sub-pixel sp in the sub-pixel row spH is connected to the first scan line S1, and the other one is connected to the second scan line S2. A control terminal of the second switching transistor T2 of multiple sub-pixels sp in the sub-pixel row spH is connected to the third scanning line S3. The display panel is further provided with shift register units, the first scanning line S1 and the second scanning line S2 are connected to two adjacent stages of the cascaded shift register units, and the third scanning line S3 is connected to another set of cascaded shift register units.

As shown in FIG. 3, the display area AA includes a power-supply line 30 and a reference signal line 40 that extend along the first direction y, the power-supply line 30 is connected to the power-supply lead 22, and the reference signal line 40 is connected to the reference lead 23. The sub-pixel sp includes a light emitting device and a pixel circuit 50. The pixel circuit 50 includes a driving transistor Tm, a first switch transistor T1, a second switch transistor T2 and a storage capacitor C. A control terminal of the driving transistor Tm is connected to the first node N1, a first electrode of the driving transistor Tm is connected to the power supply line 30, a second electrode of the driving transistor Tm is connected to the second node N2, a first electrode of the first switching transistor T1 is connected to the data line 10, a second electrode of the first switching transistor T1 is connected to the first node N1, a first electrode of the second switching transistor T2 is connected to the reference signal line 40, a second electrode of the second switching transistor T2 is connected to the second node N2, one plate of the storage capacitor C is connected to the first node N1, and the other plate of the storage capacitor C is connected to the second node N2. All the transistors in the pixel circuit 50 are n-type transistors.

In addition, as shown in FIG. 3, a first scan line S1, a second scan line S2 and a third scan line S3 that extend along the second direction x are arranged in the display area AA; the first data line 11 is connected to two adjacent sub-pixels sp belonging to a same sub-pixel row spH in the second direction x, and the second data line 12 is connected to two adjacent sub-pixels sp belonging to a same sub-pixel row spH to the second direction x. One of the first switch transistor T1 of the odd-numbered sub-pixel sp and the first switch transistor T1 of the even-numbered sub-pixel sp in the sub-pixel row spH is connected to the first scan line S1, and the other one is connected to the second scan line S2. A control terminal of the second switching transistor T2 of multiple sub-pixels sp in the sub-pixel row spH is connected to the third scanning line S3. The first scan line S1 and the second scan line S2 are respectively connected to two adjacent stages of cascaded shift register units. FIG. 3 shows an embodiment designed by using a DGLD technology.

FIG. 4 is a signal timing sequence diagram according to an embodiment of the present disclosure. FIG. 4 shows signal sequences of the first scan line S1, the second scan line S2 and the third scan line S3 connected to one pixel circuit row, which can be used to drive the sub-pixel row spH in FIG. 3. For example, S1 represents the control signal provided by the first scan line S1, S2 represents the control signal provided by the second scan line S2, and S3 represents the control signal provided by the third scan line S3. As shown in FIG. 4, during the period t0 in which the sub-pixel row is driven to operate, firstly, the first scan line S1 provides a high-level enable signal and the second scan line S2 provides a non-enable signal, the first scan line S1 controls the first switch transistor T1 connected thereto to be turned on, and meanwhile, the first data line 11 and the second data line 12 write data voltages to the first node N1 of the pixel circuit 50 respectively through the corresponding first switch transistors T1; then, the first scan line S1 provides the non-enable signal and the second scan line S2 provides the high-level enable signal, the second scan line S2 controls the first switch transistor T1 connected thereto to be turned on, and meanwhile, the first data line 11 and the second data line 12 write data voltages to the first node N1 of the pixel circuit 50 respectively through the corresponding first switch transistor T1; the third scan line S3 provides the high-level enable signal to control the second switch transistor T2 of each pixel circuit in the sub-pixel row spH to be turned on and write a reference voltage to the second node N2, and the period in which the third scan line S3 provides the high-level enable signal covers the period in which the first scan line S1 provides the high-level enable signal and the period in which the second scan line S2 provides the high-level enable signal.

In some embodiments as shown in FIG. 3, one first data line 11 and one second data line 12 can respectively drive two adjacent columns of sub-pixels, thereby reducing the number of data lines 10 arranged in the display area AA. With reference to the timing sequence diagram provided in FIG. 4, it can be understood that the charging time of each sub-pixel sp in the time period t0 in which the row of driving sub-pixels operates is shortened, and the signal transmission frequency of the data line 10 is higher, exactly because one first data line 11 and one second data line 12 respectively drive two adjacent columns of sub-pixels. As a result, the data signal transmission frequency of the data leads 21 in the non-display area NA is higher, and the signal crosstalk problem between adjacent data leads 21 is more serious. By adopting the design of the embodiments of the present disclosure, the power-supply lead 22 or the reference lead 23 is arranged between the adjacent first data lead 211 and the adjacent second data lead 212, so that the signal crosstalk between the adjacent first data lead 211 and the adjacent second data lead 212 can be shielded during the display period, the accuracy of the transmission data voltage on the data lead 21 is improved, the problem that two adjacent columns of sub-pixels interfere with each other and cause poor display in the development process of the DGLD OLED TV is solved, and the display quality can be improved. In addition, in the DGLD architecture of an embodiment as shown in FIG. 3, the number of the data lines 10 in the display area AA is halved, and thus the number of the data leads 21 in the non-display area NA is halved, so that the arrangement space for arranging the power-supply leads 22 and the reference leads 23 can be reserved. The addition of the power-supply lead 22 between the adjacent first data lead 211 and the second data lead 212 can improve the in-plane power-supply voltage uniformity, thereby improving the display uniformity.

FIG. 5 is a partial schematic diagram of a display panel according to an embodiment of the present disclosure. As shown in FIG. 5, the display area AA includes a power-supply line 30 and a reference signal line 40 that extend along the first direction y, the power-supply line 30 is connected to the power-supply lead 22, and the reference signal line 40 is connected to the reference lead 23. The sub-pixel sp includes a light emitting device and a pixel circuit 50. The structure of the pixel circuit 50 is the same as that in the embodiment as shown in FIG. 3, which will not be elaborated again.

FIG. 5 illustrate four sub-pixels sp in the display area AA, the connection manner of the data lines 10 and the sub-pixels sp in the display area AA in FIG. 5 is the same as that in the embodiment as shown in FIG. 2, which illustrates a red light-emitting device PD-r, a green light-emitting device PD-g, a blue light-emitting device PD-b and a white light-emitting device PD-w, the first data line 11 is connected to the pixel circuits 50 corresponding to the red light-emitting device PD-r and the blue light-emitting device PD-b, and the second data line 12 is connected to the pixel circuits 50 corresponding to the green light-emitting device PD-g and the white light-emitting device PD-w. Multiple sub-pixels sp in the display area AA are arranged in a sub-pixel row spH in the second direction x. FIG. 5 shows four sub-pixels sp in one sub-pixel row spH. A fourth scan line S4 and a fifth scan line S5 extending in the second direction x are arranged in the display area AA. The fourth scan line S4 is connected to the control terminal of the first switch transistor T1 in the sub-pixel row spH, and the fifth scan line S5 is connected to the control terminal of the second switch transistor T2 in the sub-pixel row spH. A shift register unit is further arranged in the display panel, the fourth scanning line S4 is connected to one stage of a set of cascaded shift register units, and the fifth scanning line S5 is connected to one stage of another set of cascaded shift register units.

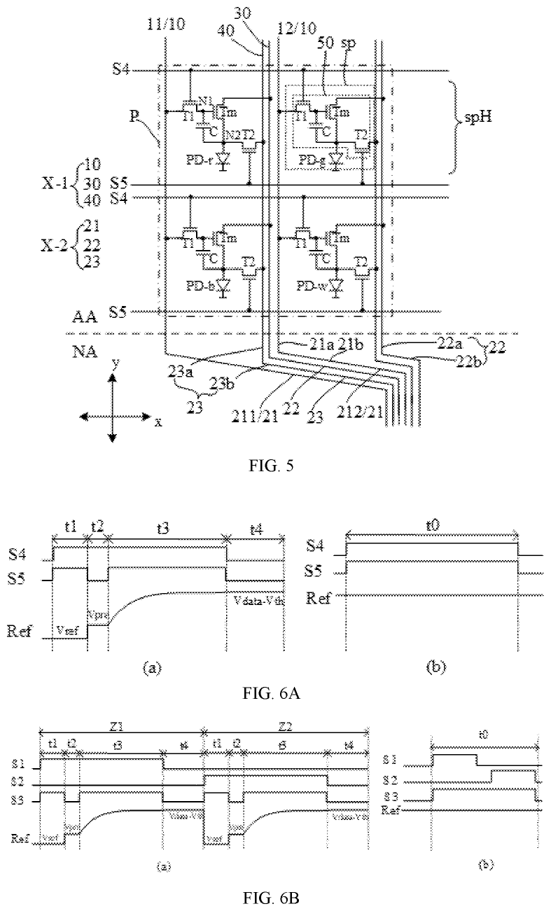

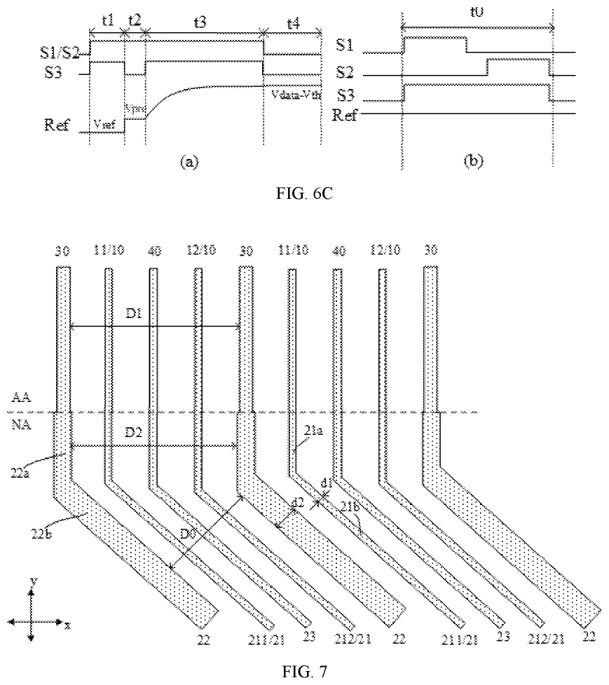

FIG. 6A is a timing sequence diagram according to an embodiment of the present disclosure. The timing sequence provided in FIG. 6A can drive the pixel circuit in FIG. 5. FIG. 6A (a) shows an operating sequence for driving the pixel circuit 50 to operate in the compensation mode. FIG. 6A (b) shows an operating sequence for driving the pixel circuit 50 to operate in the display mode. In the figures, S4 represents a control signal provided by the fourth scan line S4, S5 represents a control signal provided by the fifth scan line S5, and Ref represents a signal provided on the reference signal line 40.

In the compensation mode, as shown in FIG. 6A (a), in an initialization phase t1, the fourth scanning line S4 and the fifth scanning line S5 provide high-level enable signals to control the first switching transistor T1 and the second switching transistor T2 to be turned on, respectively; the first switching transistor T1 is turned on, and the data voltage Vdata is written to the first node through the data line; and the second switching transistor T2 is turned on, and the reference signal Vref is written to the second node through the reference signal line.

In a pre-charging phase t2, the fifth scan line S5 provides a low-level non-enable signal to control the second switch T2 to be turned off, and the pre-charging voltage Vpre is written on the reference signal line 40.

In a discharging phase t3, the fifth scanning line S5 provides a high-level enable signal to control the second switch transistor T2 to be turned on, the driving transistor Tm is turned on under the control of the potential of the first node N1, the second node N2 is charged by using the power signal on the power supply line 30; when Vgs=Vth, the driving transistor Tm is turned off, the second node N2 is charged until the potential thereof reaches Vdata−Vth, where Vth represents the threshold voltage of the driving transistor Tm, and Vgs is the gate-source voltage difference of the driving transistor Tm. Since the second switch transistor T2 is turned on, the reference signal line 40 and the second node N2 are turned on, and the potential on the reference signal line 40 jumps from Vpre to Vdata−Vth.

In a sampling phase t4, the fourth scanning line S4 and the fifth scanning line S5 respectively provide low-level non-enable signals to control the first switching transistor T1 and the second switching transistor T2 to be turned off, and the sensing signal Vdata−Vth is collected through the reference signal line 40.

Subsequently, the sensing signal collected by the reference signal line 40 is provided to an external compensation circuit, and the compensation circuit modulates the data voltage of the input image based on the sensing signal to compensate for the characteristic (threshold voltage, mobility, etc.) change of the driving transistor Tm in the pixel circuit 50. The compensation mode is a mode in which the characteristic of the driving transistor Tm in the pixel circuit 50 is sensed. In this mode, the characteristic of the driving transistor Tm may be sensed before leaving the factory, or the characteristic of the driving transistor Tm may be sensed after the display panel is used for a period of time, or the compensation mode may be inserted between the display modes.

In the display mode, as shown in FIG. 6A (b), the fourth scanning line S4 and the fifth scanning line S5 respectively control the first switching transistor T1 and the second switching transistor T2 to be turned on during the time period t0 in which the row of sub-pixels is driven to operate; the first switching transistor T1 is turned on, and the compensated data voltage Vdata is written to the first node through the data line; and the second switching transistor T2 is turned on, and the reference signal Vref is written to the second node through the reference signal line. The driving transistor Tm is turned on and generates a driving current under the control of the compensated data voltage Vdata, and the driving current is provided to the light emitting device PD, so that the light emitting device PD emits light.

The pixel circuit 50 according to the embodiment as shown in FIG. 5 may operate in the time sequence as shown in FIG. 6A, and the change of the characteristic of the driving transistor Tm can be compensated in an external compensation manner, so as to improve display uniformity.

For example, FIG. 6B is a timing sequence diagram according to an embodiment of the present disclosure. The timing sequence provided in FIG. 6B (a) can drive multiple pixel circuits in one sub-pixel row spH in FIG. 3 to operate in the compensation mode. The timing sequence provided in FIG. 6B (b) can drive multiple pixel circuits in one sub-pixel row spH in FIG. 3 to operate in a display mode. In the figures, S1 represents the control signal provided by the first scan line S1, S2 represents the control signal provided by the second scan line S2, S3 represents the control signal provided by the third scan line S3, and Ref represents the signal on the reference signal line 40.

Referring to FIG. 3, in the first time period Z1, the even-numbered pixel circuit 50 in the sub-pixel row spH sequentially performs the initialization phase t1, the pre-charging phase t2, the discharging phase t3 and the sampling phase t4. In the initialization phase t1, the first scan line S1 and the third scan line S3 respectively provide a high-level enable signal to control the first switch T1 and the second switch T2 to be turned on, the first switch T1 is turned on, and the data voltage Vdata is written to the first node N1 through the data line 10. In the pre-charging phase t2, the third scan line S3 provides a non-enable signal to control the second switch T2 to be turned off, and the pre-charging voltage Vpre is written to the reference signal line 40. In the discharging phase t3, the third scanning line S3 provides a high-level enable signal to control the second switch transistor T2 to be turned on, the driving transistor Tm is turned on under the control of the potential of the first node N1, the second node N2 is charged by using the power signal on the power-supply line 30, the second node N2 is charged until the potential thereof reaches Vdata−Vth, the reference signal line 40 is connected to the second node N2, and the potential on the reference signal line 40 jumps from Vpre to Vdata−Vth. In the sampling phase t4, the first scan line S1 and the third scan line S3 respectively provide a non-enable signal to control the first switch transistor T1 and the second switch transistor T2 to be turned off, and the sensing signal Vdata−Vth is collected through the reference signal line 40. Thus, the even-numbered pixel circuit 50 in the sub-pixel row spH completes the acquisition of the sensing signal through the corresponding reference signal line 40.

In a second period Z2, the odd-numbered pixel circuit 50 in the sub-pixel row spH sequentially performs the initialization phase t1, the pre-charging phase t2, the discharging phase t3 and the sampling phase t4. In the initialization phase t1, the second scan line S2 and the third scan line S3 respectively provide a high-level enable signal to control the first switch T1 and the second switch T2 to be turned on, the first switch T1 is turned on, and the data voltage Vdata is written to the first node N1 through the data line 10. In the pre-charging phase t2, the third scan line S3 provides a non-enable signal to control the second switch T2 to be turned off, and the pre-charging voltage Vpre is written to the reference signal line 40. In the discharging phase t3, the third scanning line S3 provides a high-level enable signal to control the second switch transistor T2 to be turned on, the driving transistor Tm is turned on under the control of the potential of the first node N1, the second node N2 is charged by using the power signal on the power-supply line 30, the second node N2 is charged until the potential thereof reaches Vdata−Vth, and the potential on the reference signal line 40 jumps from Vpre to Vdata−Vth. In the sampling phase t4, the second scan line S2 and the third scan line S3 respectively provide non-enable signals to control the first switch transistor T1 and the second switch transistor T2 to be turned off, and the sensing signal Vdata−Vth is collected through the reference signal line 40. In this way, the odd-numbered pixel circuit 50 in the sub-pixel row spH completes the collection of the sensing signal through the corresponding reference signal line 40.

The timing sequence provided in FIG. 6B (b) can drive multiple pixel circuits in one sub-pixel row spH in FIG. 3 to operate in the display mode, and the sequence in FIG. 6B (b) is the same as that in FIG. 4, which will not be elaborated again. The pixel circuit 50 provided by the embodiment of FIG. 3 may operate in the time sequence shown in FIG. 6B, and the characteristic change of the driving transistor Tm is compensated in an external compensation manner, so as to improve display uniformity.

FIG. 6B illustrates the sequence of the odd-numbered pixel circuit and the even-numbered pixel circuit in the sub-pixel row spH in FIG. 3 respectively collecting the sensing signals. FIG. 6C is a timing sequence diagram according to an embodiment of the present disclosure. FIG. 6C (a) shows that, in the compensation mode, the first scan line S1 and the second scan line S2 provide a same signal, so that the odd-numbered pixel circuit and the even-numbered pixel circuit in the pixel circuit row together sequentially execute the initialization phase t1, the pre-charging phase t2, the discharging phase t3 and the sampling phase T4. That is, the odd-numbered pixel circuit and the even-numbered pixel circuit in the sub-pixel row spH may collect the sensing signal simultaneously.

In some embodiments, as shown in FIG. 1 or FIG. 2, the display area AA includes a power-supply line 30 and a reference signal line 40 extending along the first direction y, the power-supply line 30 is connected to the power-supply lead 22, and the reference signal line 40 is connected to the reference lead 23. That is, the power-supply lead 22 transmits a signal required by the power-supply line 30, and the reference lead 23 transmits a signal required by the reference signal line 40. In the display area AA, multiple sub-pixels sp are arranged in an array, and a power-supply line 30 and a reference signal line 40 need to be used for driving each sub-pixel sp. The first data lines 11 and the second data lines 12 are alternately routed in the display area AA, that is, no other data line 10 is arranged between the first data line 11 and the second data line 12 adjacent to each other. In addition, a power-supply line 30 and/or a reference signal line 40 are disposed between the first data line 11 and the second data line 12 adjacent to each other in the display area AA, so that the power-supply line 30 and the reference signal line 40 respectively provide signals to the sub-pixels sp, thereby avoiding that the distance between the power-supply line 30 and the sub-pixel sp connected thereto is excessive, the voltage drop is increased to affect display uniformity, and further avoiding that the distance between the reference signal line 40 and the sub-pixel sp connected thereto is excessive large, and the voltage drop is increased to affect the accuracy of the sensing signal in the compensation mode and further affect the display uniformity.

In some embodiments, as shown in FIG. 3 and FIG. 5, the display area AA includes multiple power-supply lines 30 extending along the first direction y. The power-supply leads 22 include a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y. The power-supply lines 30 are connected to the power-supply leads 22 in one-to-one correspondence. In a related technical solution, multiple power-supply lines are arranged in the display area AA, a power-supply bus is arranged in the non-display area NA, the power-supply lines are arranged to be connected to corresponding power-supply terminals (configured to be connected to a display driving chip) through the power-supply bus, the power-supply bus has a certain width in the non-display area, and the power-supply bus and the arranged data leads are located in different film layers and are insulated from and overlapped with each other. For example, a first metal layer and a second metal layer are arranged in the display panel, the data lines in the display area are located in the first metal layer, the scan lines in the display area are located in the second metal layer, the data leads in the non-display area are located in the first metal layer, and the power-supply bus in the non-display area is arranged in the second metal layer. In the related art, the power-supply bus is connected to the power-supply terminals by arranging the incoming ends, the number of the incoming ends is small, the incoming ends are basically arranged at the edge positions or the middle positions of multiple leads, and the types of the leads on the two sides of the incoming ends are specially designed. That is, in the related art, no power-supply lead is disposed between adjacent data leads. In contrast, according to some embodiments of the present disclosure, the power-supply lines 30 are connected to the power-supply leads 22 in one-to-one correspondence, so that on the one hand, the power-supply leads 22 can be used to shield signals between the adjacent first data leads 211 and second data leads 212, thereby preventing signal crosstalk between the first data leads 211 and the second data leads 212 adjacent to each other from affecting display quality; and on the other hand, the voltage drop uniformity of each power-supply line 30 in the display area AA can be improved, thereby improving the display uniformity.

In some embodiments, as shown in FIG. 3 and FIG. 5, the display area AA includes multiple reference signal lines 40 extending along the first direction y; the reference lead 23 includes a third line segment 23a and a fourth line segment 23b, the third line segment 23a is connected between the reference signal line 40 and the fourth line segment 23b, the third line segment 23a extends along the first direction y, and an acute angle is formed between an extending direction of the fourth line segment 23b and the first direction y; and the reference signal lines 40 are connected to the reference leads 23 in one-to-one correspondence. With reference to the working process of the pixel circuit 50 shown in FIG. 3 and FIG. 5, the reference signal line 40 needs to collect a sensing signal when the pixel circuit operates in the compensation mode, and the reference signal lines 40 are arranged to be connected to the reference leads 23 in a one-to-one correspondence manner, so as to ensure that each reference signal line 40 is used to collect a corresponding sensing signal, to sense a characteristic of the driving transistor Tm, and further to drive the pixel circuit by using a data voltage after sensing compensation in the display mode, to implement external compensation for the characteristic of the driving transistor Tm. Moreover, when the pixel circuit operates in the display mode, a constant voltage signal is provided to the reference signal line 40 through the reference lead 23. In the normal display period of the display panel, the reference lead 23 arranged between the adjacent first data lead 211 and the second data lead 212 can shield signals, thereby reducing signal crosstalk between the first data lead 211 and the second data lead 212 that transmit high-frequency data voltage, improving accuracy of data voltage transmission on the data lead 21, and improving display quality.

FIG. 7 is a schematic diagram of a display panel according to an embodiment of the present disclosure. FIG. 7 merely simplifies the structure of the display panel, and does not show the pixel circuit and the light-emitting device in the display area AA. As shown in FIG. 7, the power-supply lead 22 includes a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y; and the power-supply lines 30 are connected to the power-supply leads 22 in one-to-one correspondence. A spacing between two adjacent power-supply lines 30 in the display area AA is D1, and a spacing between two first line segments 22a of two adjacent power-supply leads 22 in the non-display area NA is D2, where D1>D2. In this embodiment, the power-supply lines 30 are connected to the power-supply leads 22 in one-to-one correspondence, and the power-supply leads 22 play a role of shielding signals between the first data leads 211 and the second data leads 212 adjacent to each other. Moreover, the spacing between two first line segments 22a of two adjacent power-supply leads 22 in the non-display area NA is set to be smaller than the spacing between adjacent power-supply lines 30 in the display area AA. Since multiple signal leads in the non-display area NA are arranged in sequence and the transistor structure of the pixel circuit does not need to be arranged in the non-display area NA, the width of each power-supply lead 22 can be set to be relatively large, so that the spacing between two first line segments 22a of two adjacent power-supply leads 22 is relatively small. Therefore, the spacing between the power-supply lead 22 and the adjacent data lead 21 can be appropriately reduced, thereby improving the shielding capability of the power-supply lead 22 for high-frequency data signals on the data lead 21.

As shown in FIG. 7, a distance between two second line segments 22b of two adjacent power-supply leads 22 is D0, where D0<D2. Since there is an acute angle between the extending direction of the second line segment 22b and the first direction y, the distance between two adjacent second line segments 22b is calculated based on the distance between the two second line segments 22b perpendicular to the extending direction of the second line segment 22b.

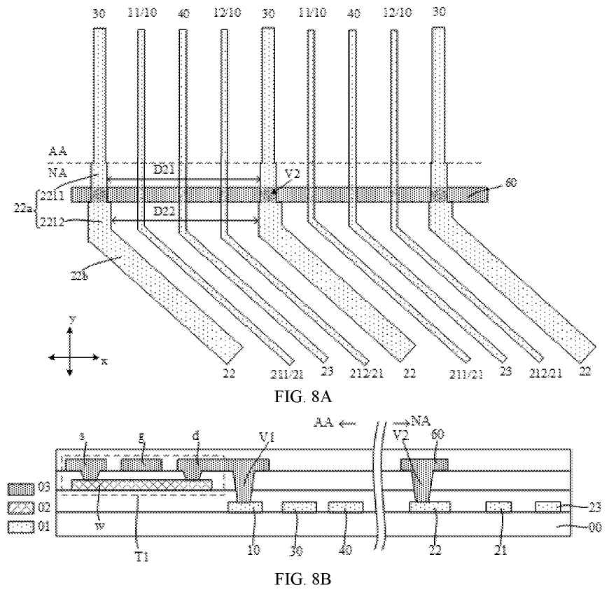

FIG. 8A is a schematic diagram of a display panel according to an embodiment of the present disclosure. FIG. 8A only simplifies the structure of the display panel, and does not show the pixel circuit and the light-emitting device in the display area AA. As shown in FIG. 8A, the display area AA includes a power-supply line 30 extending along a first direction y, the power-supply lead 22 includes a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y. It can also be seen from FIG. 8A that a distance between two adjacent power-supply lines 30 is greater than a distance between two first line segments 22a of two adjacent power-supply leads 22.

In addition, it can be seen from FIG. 8A that the first line segment 22a includes a first sub-segment 2211 and a second sub-segment 2212, and the second sub-segment 2212 is connected between the first sub-segment 2211 and the second line segment 22b. A spacing between two adjacent second sub-segments 2212 is D21, and a spacing between two adjacent first sub-segments 2211 is D22, where D21 <D22. The signal leads in the non-display area NA, such as the power-supply leads 22, are arranged to have line segments with different extending directions, and multiple signal leads are led out from the boundaries of the display area AA and the non-display area NA, and then gradually converge to form a fan-shaped arrangement. In some embodiments as shown in FIG. 8A, the second sub-segment 2212 is connected between the first sub-segment 2211 and the second line segment 22b. Compared with the first sub-segment 2211, the second sub-segment 2212 is relatively far away from the display area AA. The spacing between two adjacent second sub-segments 2212 is smaller, that is, the spacing between adjacent power-supply leads 22 is smaller at a position close to the convergence of multiple signal leads. For example, the spacing between two adjacent first sub-segments 2211 may be different from the spacing between two adjacent second sub-segments 2212 by adjusting the widths of the sub-segments on the power-supply lead 22. On the one hand, at a position close to the convergence of multiple signal leads, the distance between two adjacent second sub-segments 2212 is set to be smaller, so that the distance from the data lead 21 between the two second sub-segments 2212 to the power-supply lead 22 is reduced, thereby enhancing the shielding capability of the power-supply lead 22 for high-frequency signals on the data lead 21. On the other hand, the first sub-segment 2211 and the second sub-segment 2212 may be set to have different widths, so that the line width of the first line segment 22a in the power-supply lead 22 gradually changes, and the distribution change of the surrounding electromagnetic field caused by sudden change of the line width of the power-supply lead 22 is avoided, thereby avoiding poor signal transmission caused by sudden change of the line width and signal crosstalk caused by inductive coupling.

In some embodiments, as shown in FIG. 8A, the width of the second sub-segment 2212 is greater than the width of the first sub-segment 2211. By adjusting the width relationship between the first sub-segment 2211 and the second sub-segment 2212, the spacing between two adjacent second sub-segments 2212 can be smaller than the spacing between two adjacent first sub-segments 2211. Therefore, the distance between two adjacent second sub-segments 2212 can be set smaller at a position close to multiple signal lead converging positions, so that the distance from the data lead 21 between the two second sub-segments 2212 to the power-supply lead 22 is reduced, thereby enhancing the shielding capability of the power-supply lead 22 for high-frequency signals on the data lead 21. In addition, the line width of the first line segment 22a in the power-supply lead 22 is configured to gradually change, so that the distribution change of the surrounding electromagnetic field caused by sudden change of the line width of the power-supply lead 22 can be avoided, thereby avoiding signal transmission defects caused by sudden change of the line width and signal crosstalk caused by inductive coupling.

In some embodiments, as shown in FIG. 8A, the non-display area NA includes a power-supply bus 60 extending along a second direction x, and the second direction x intersects the first direction y. The power-supply bus 60 is electrically connected to a power-supply lead 22. The power-supply lead 22 includes a first line segment 22a and a second line segment 22b, the first line segment 22a includes a first sub-segment 2211 and a second sub-segment 2212, and the second sub-segment 2212 is connected between the first sub-segment 2211 and the second line segment 22b. The second sub-segment 2212 is located at a side of the power-supply bus 60 away from the display area AA. The power-supply bus 60 is arranged in the non-display area NA, and the power-supply bus 60 is electrically connected to the power-supply leads 22, so that the voltage drop between the power-supply leads 22 can be uniformed in the non-display area NA, and the power voltage uniformity of the power-supply line 30 at the junction of the display area AA and the non-display area NA is improved, thereby facilitating the improvement of the display uniformity. In addition, the line segment located at the side of the power-supply bus 60 close to the display area AA is set as the first sub-segment 2211, and the line segment located at the side of the power-supply bus 60 away from the display area AA is set as the second sub-segment 2212, which not only realizes the design of gradually changing the line width of the power-supply lead 22, but also enables all the first sub-segment 2211 to be electrically interconnected through the power-supply bus extending in the second direction x at the position where the line width is reduced, thereby compensating the voltage drop change caused by the line width change, and improving the uniformity of voltage drop of power supply on each first sub-segment 2211.

In some embodiments, the data lead 21, the power-supply lead 22 and the reference lead 23 are located in a same layer, the wiring manner of the three leads are substantially the same, and the three leads may be manufactured in a same process. Therefore, the process is simple. Moreover, the film layer structure of the display panel can be relatively simple, the process time consumption is short, and the manufacturing cost is reduced.

FIG. 8B is a schematic cross-sectional view of a display panel according to an embodiment of the present disclosure. In order to illustrate the film layer relationship in the display panel, FIG. 8B shows a first switch transistor T1 located in the display area AA, and the film layer layout of the driving transistor Tm and the second switch transistor T2 in the pixel circuit is substantially the same as that of the first switch transistor T1. As shown in FIG. 8B, the display panel includes a substrate 00, and a first metal layer 01, a semiconductor layer 02, and a second metal layer 03 that are located at a side of the substrate 00. The first metal layer 01, the semiconductor layer 02, and the second metal layer 03 are arranged sequentially away from the substrate 00. The active layer of the first switch transistor T1 is located in the semiconductor layer 02. The material of the semiconductor layer 02 includes a metal oxide, such as indium gallium zinc oxide. The gate electrode g, the source electrode s and the drain electrode d of the first switch transistor T1 are all located in the second metal layer 03. The power-supply line 30, the data line 10 and the reference signal line 40 in the display area AA are all located in the first metal layer 01. It can be seen from FIG. 8B that the drain electrode d of the first switch transistor T1 is connected to the data line 10 through the first via hole V1 penetrating the insulating layer. It can be understood that the power-supply line 30 is connected to the electrode of the driving transistor Tm located in the second metal layer 03 through the corresponding via hole, and the reference signal line 40 is connected to the electrode of the second switching transistor T2 located in the second metal layer 03 through the corresponding via hole. In addition, the scan line arranged in the display area AA and extending along the second direction x as illustrated in FIG. 3 or FIG. 5 may be located in the second metal layer 03.

The power-supply bus 60 in the non-display area NA is located in the second metal layer 03, the power-supply lead 22 is located in the first metal layer 01, and the power-supply bus 60 and the power-supply lead 22 are connected through the second via hole V2 penetrating through the insulating layer. In addition, the data lead 21 and the reference lead 23 in the non-display area NA are also located in the first metal layer 01.

As shown in FIG. 8B, the power-supply bus 60 and the power-supply lead 22 are located in different layers, and the power-supply bus 60 is electrically connected to the power-supply lead 22 through a second via hole V2 penetrating through the insulating layer. Due to different wiring manners of the power-supply bus 60 and the power-supply leads 22, the power-supply bus 60 and the power-supply leads 22 are disposed in different layers, so that all the power-supply leads 22 can be connected to the power-supply bus 60, thereby balancing the voltage drop difference between the power-supply leads 22.

The arrangement of the signal lines in the display area AA and the arrangement of the leads in the non-display area NA in the embodiments as shown FIG. 7 and FIG. 8A are the same as those in the embodiment as shown FIG. 1. In some embodiments, as shown in FIG. 2, the power-supply lines 30 are connected to the power-supply leads 22 in one-to-one correspondence, the power-supply leads 22 include a first line segment 22a and a second line segment 22b, a spacing between two adjacent power-supply lines 30 in the display area AA is D1, and a spacing between two first line segments 22a of two adjacent power-supply leads 22 in the non-display area NA is D2, where D1>D2.

In some embodiments as shown in FIG. 2, as shown in the embodiment of FIG. 8A, the first line segment 22a may include a first sub-segment 2211 and a second sub-segment 2212, and the second sub-segment 2212 is connected between the first sub-segment 2211 and the second line segment 22b. The spacing between two adjacent second sub-segments 2212 is D21, and the spacing between two adjacent first sub-segments 2211 is D22, where D 21<D22. The width of the second sub-segment 2212 is greater than the width of the first sub-segment 2211. Further, a power-supply bus 60 extending along the second direction x may also be added in some embodiments as shown FIG. 2, and the power-supply bus 60 is electrically connected to the power-supply lead 22, which will not be illustrated by accompanied drawings herein.

In some embodiments, multiple sub-pixels sp include a first sub-pixel, a second sub-pixel, a third sub-pixel, and a fourth sub-pixel having different colors; the first sub-pixel, the second sub-pixel, the third sub-pixel, and the fourth sub-pixel form a pixel unit; and the first sub-pixel, the second sub-pixel, the third sub-pixel, and the fourth sub-pixel are respectively one of a red sub-pixel R, a green sub-pixel G, a blue sub-pixel B, and a white sub-pixel W. As shown in FIG. 1 and FIG. 3, the red sub-pixel R, the green sub-pixel G, the blue sub-pixel B and the white sub-pixel W are arranged in the second direction x to form a pixel unit P. As shown in FIG. 2 and FIG. 5, the red sub-pixel R, the green sub-pixel G, the blue sub-pixel B and the white sub-pixel W are arranged in 2*2 to form a pixel unit P. FIG. 1 illustrates that the red sub-pixel R, the green sub-pixel G, the blue sub-pixel B and the white sub-pixel W in the pixel unit P are sequentially arranged. It should be understood that the arrangement order of the sub-pixels sp of four colors can be changed, and FIG. 1 only illustrates one optional situation. For example, in the pixel unit P, a green sub-pixel G, a blue sub-pixel B, a white sub-pixel W and a red sub-pixel R may be sequentially arranged. Likewise, the arrangement order of the four color sub-pixels sp in the pixel unit P in FIG. 2 is merely illustrative, and is not intended to limit the present disclosure.

As shown in FIG. 3 and FIG. 5, the display area AA includes a power-supply line 30 and a reference signal line 40 extending in the first direction y, the power-supply line 30 is connected to the power-supply lead 22, and the reference signal line 40 is connected to the reference lead 23. The display panel includes a signal line X-1 located in the display area AA and a signal lead X-2 located in the non-display area NA, the signal line X-1 includes a data line 10, a power-supply line 30 and a reference signal line 40, and the signal lead X-2 includes a data lead 21, a power-supply lead 22 and a reference lead 23. The arrangement order of the signal lines X-1 connected to a same pixel unit P is the same as the arrangement order of the signal leads X-2. Taking FIG. 3 as an example, the arrangement order of the signal lines X-1 connected to a same pixel unit P is a power-supply line 30, a first data line 11, a reference signal line 40, a second data line 12, and a power-supply line 30 in sequence, and the arrangement order of the signal leads X-2 is a power-supply lead 22, a first data lead 211, a reference lead 23, a second data lead 212, and a power-supply lead 22 in sequence. The same arrangement order herein refers to the arrangement order of the transmitted signals.

In some embodiments of the present disclosure, the arrangement order of the signal lines X-1 connected to a same pixel unit P is the same as the arrangement order of the signal leads X-2, so that the signal lines X-1 in the display area AA can be correspondingly connected to the signal leads X-2 in the non-display area NA in sequence. The driving requirement of the wiring in the display area AA for driving the pixel unit P is met, and the power-supply lead 22 and the reference lead 23 can be arranged at a proper position in the non-display area NA. The power-supply lead 22 and/or the reference lead 23 can shield signals between the first data lead 211 and the second data lead 212 adjacent to each other, thereby preventing the signal crosstalk of the high-frequency data voltage between the first data lead 211 and the second data lead 212 adjacent to each other.

In some embodiments, as shown in FIG. 3 or FIG. 5, the power-supply lead 22 includes a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y. The reference lead 23 includes a third line segment 23a and a fourth line segment 23b, and the third line segment 23a is connected between the reference signal line 40 and the fourth line segment 23b. The third line segment 23a extends along the first direction y, and an acute angle is formed between an extending direction of the fourth line segment 23b and the first direction y. The data lead 21 includes a fifth line segment 21a and a sixth line segment 21b, the fifth line segment 21a is connected between the data line 10 and the sixth line segment 21b, the fifth line segment 21a extends along the first direction y, and an acute angle is formed between an extending direction of the sixth line segment 21b and the first direction y. In an embodiment, the arrangement area of multiple signal leads in the non-display area NA includes a center line extending along the first direction y, and the signal leads at both sides of the center line are approximately symmetrically designed. At a side of the center line, the second line segment 22b, the fourth line segment 23b, and the sixth line segment 21b extend in a same direction. In this way, the wiring manners of the power-supply lead 22, the reference lead 23, and the data lead 21 are substantially the same, so that the signal leads are led out from a boundary between the display area AA and the non-display area NA, and then are gradually gathered to form a fan-shaped arrangement. Accordingly, the signal leads are connected to the corresponding terminals, and the display driving chip provides signals to the signal leads through the corresponding terminals.

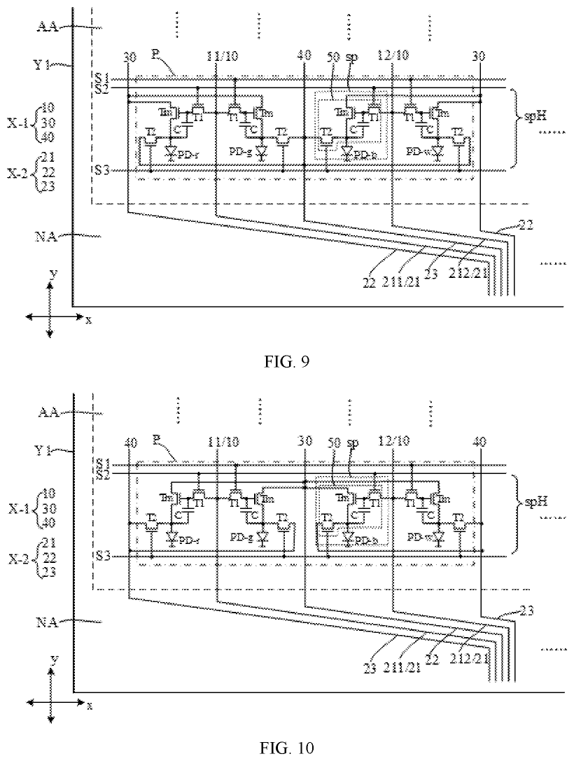

FIG. 9 is a schematic diagram of a display panel according to an embodiment of the present disclosure. FIG. 9 illustrates a local position of a display panel. As shown in FIG. 9, the display panel includes a first edge Y1 extending along the first direction y. Among the signal lines X-1 connected to a same pixel unit P, a distance from at least one power-supply line 30 to the first edge Y1 is less than a distance from the data line 10 to the first edge Y1. In FIG. 9, the arrangement order of the signal lines X-1 connected to a same pixel unit P is the power-supply line 30, the first data line 11, the reference signal line 40, the second data line 12, and the power-supply line 30 in sequence, so that the distance from at least one power-supply line 30 to the first edge Y1 is less than the distance from the data line 10 to the first edge Y1. Correspondingly, the arrangement order of the signal leads X-2 connected to a same pixel unit P is the power-supply lead 22, the first data lead 211, the reference lead 23, the second data lead 212, and the power-supply lead 22, and at least one power-supply lead 22 is arranged at a side of the data lead 21 close to the first edge Y1. Multiple pixel units P are arranged in an array in the display area AA. In some embodiments as shown in FIG. 9, the first signal line X-1 and the last signal line X-1 arranged in the display area AA are power-supply lines 30, and the first signal lead X-2 and the last signal lead X-2 arranged in the non-display area NA are power-supply leads 22. The first power-supply line 30 and the last power-supply line 30 arranged in the display area AA can shield signals at the edge of the display area AA to prevent the signals of the wiring in the non-display area NA from interfering with the signals on the data lines 10 in the display area AA. In addition, the first power-supply lead 22 and the last power-supply lead 22 arranged in the non-display area NA can cooperate with each other to shield external signals, thereby avoid interference to the signal lead X-2 in the fan-out area.

FIG. 10 is a schematic diagram of a display panel according to an embodiment of the present disclosure. FIG. 10 illustrates a local position of a display panel. As shown in FIG. 10, the display panel includes a first edge Y1 extending along a first direction y. Among the signal lines X-1 connected to a same pixel unit P, a distance from at least one reference signal line 40 to the first edge Y1 is less than a distance from the data line 10 to the first edge Y1. In FIG. 10, the arrangement order of the signal lines X-1 connected to a same pixel unit P is the reference signal line 40, the first data line 11, the power-supply line 30, the second data line 12, and the reference signal line 40 in sequence, and the distance from at least one reference signal line 40 to the first edge Y1 is less than the distance from the data line 10 to the first edge Y1. Correspondingly, the arrangement order of the signal leads X-2 connected to a same pixel unit P is the reference lead 23, the first data lead 211, the power-supply lead 22, the second data lead 212, and the reference lead 23, and at least one reference lead 23 is arranged at a side of the data lead 21 close to the first edge Y1. Multiple pixel units P are arranged in an array in the display area AA. In some embodiments as shown in FIG. 10, it can be realized that the first signal line X-1 and the last signal line X-1 arranged in the display area AA are the reference signal line 40, and the first signal lead X-2 and the last signal lead X-2 arranged in the non-display area NA are the reference lead 23. The first reference signal line 40 and the last reference signal line 40 arranged in the display area AA can shield signals at least during the display period, so as to prevent the signal of the wiring in the non-display area NA from interfering with the signal on the data line 10 in the display area AA. Moreover, the first reference lead 23 and the last reference lead 23 arranged in the non-display area NA can cooperate with each other to shield the external signals, and at least during the display period, the external signal can be prevented from interfering with the signal lead X-2 in the fan-out area.

In some embodiments of the present disclosure, multiple sub-pixels sp include a first sub-pixel, a second sub-pixel, a third sub-pixel, and a fourth sub-pixel of different colors; the first sub-pixel, the second sub-pixel, the third sub-pixel, and the fourth sub-pixel form a pixel unit P; and the first sub-pixel, the second sub-pixel, the third sub-pixel, and the fourth sub-pixel are respectively one of a red sub-pixel R, a green sub-pixel G, a blue sub-pixel B, and a white sub-pixel W. The first sub-pixel, the second sub-pixel, the third sub-pixel and the fourth sub-pixel are alternately arranged in the second direction x. That is, in one pixel unit P, the first sub-pixel, the second sub-pixel, the third sub-pixel and the fourth sub-pixel are arranged in the second direction x. Multiple pixel units P are arranged along the second direction x, and multiple pixel units P are arranged along the first direction y.

FIG. 11 is a schematic diagram of a display panel according to an embodiment of the present disclosure. FIG. 11 only shows two pixel units P in one sub-pixel row spH in the display area AA. As shown in FIG. 11, for example, the first sub-pixel includes a red light-emitting device PD-r, the second sub-pixel includes a green light-emitting device PD-g, the third sub-pixel includes a blue light-emitting device PD-b, and the fourth sub-pixel includes a white light-emitting device PD-w. It can be seen from FIG. 11 that the first sub-pixel and the second sub-pixel adjacent to each other in the second direction x are connected to the first data line 11, and the third sub-pixel and the fourth sub-pixel adjacent to each other in the second direction x are connected to the second data line 12. A power-supply line 30 is provided between some of the first data lines 11 and the second data lines 12 adjacent to each other, and a reference signal line 40 is provided between some of the first data lines 11 and the second data lines 12 adjacent to each other. That is, in this embodiment, a power-supply line 30 or a reference signal line 40 is disposed between the first data line 11 and the second data line 12 adjacent to each other, thereby satisfying a driving requirement for driving the pixel circuit 50.

Under the arrangement in which the first sub-pixel, the second sub-pixel, the third sub-pixel and the fourth sub-pixel are arranged in the second direction x to form one pixel unit P, a power-supply line 30 or a reference signal line 40 is provided between the adjacent first data line 11 and second data line 12, so that, in addition to the edge position of the display area AA, most of the power-supply lines 30 in the display area AA are connected to four sub-pixel columns arranged in the second direction x as shown in FIG. 11, and one reference signal line 40 is also connected to the four sub-pixel columns arranged in the second direction x. If the number of sub-pixel columns connected to one power-supply line 30 is not too large, the power voltage received by each sub-pixel sp is relatively uniform. If the number of sub-pixel columns connected to one reference signal line 40 is not too large, the sensing signal collected by using the reference signal line 40 in the compensation mode will be relatively accurate, and correspondingly, the reference voltage received by each sub-pixel sp in the display mode is also relatively uniform.

In some embodiments of the present disclosure, as shown in FIG. 9, the arrangement order of the signal leads X-2 connected to a same pixel unit P is: the power-supply lead 22, the first data lead 211, the reference lead 23, the second data lead 212, and the power-supply lead 22 in sequence. In view of the entire of multiple signal leads X-2 arranged in the non-display area NA, the first data leads 211 and the second data leads 212 may be alternately arranged, and the power-supply leads 22 and the reference leads 23 may be alternately arranged between the first data leads 211 and second data leads 212 adjacent to each other, so that the power-supply leads 22 or the reference leads 23 are arranged between the adjacent first data leads 211 and second data leads 212.

In some embodiments, as shown in FIG. 10, the arrangement order of the signal leads connected to a same pixel unit P is: the reference lead 23, the first data lead 211, the power-supply lead 22, the second data lead 212, and the reference lead 23 in sequence. In view of the entire of multiple signal leads X-2 arranged in the non-display area NA, the first data leads 211 and the second data leads 212 may be alternately arranged, and the power-supply leads 22 and the reference leads 23 may be alternately arranged between the first data leads 211 and the second data leads 212 adjacent to each other, so that the power-supply leads 22 or the reference leads 23 are arranged between the adjacent first data leads 211 and the second data leads 212 adjacent to each other.

Both the embodiments shown FIG. 9 and FIG. 10 can realize that a power-supply lead 22 or a reference lead 23 is provided between the adjacent first data lead 211 and second data lead 212, and a signal shielding effect is achieved between the adjacent first data lead 211 and second data lead 212 by using the power-supply lead 22 or the reference lead 23 during the display period, thereby reducing signal crosstalk between the first data lead 211 and the second data lead 212 that transmit a high-frequency data voltage, improving accuracy of data voltage transmission on the data lead 21, and improving display quality.

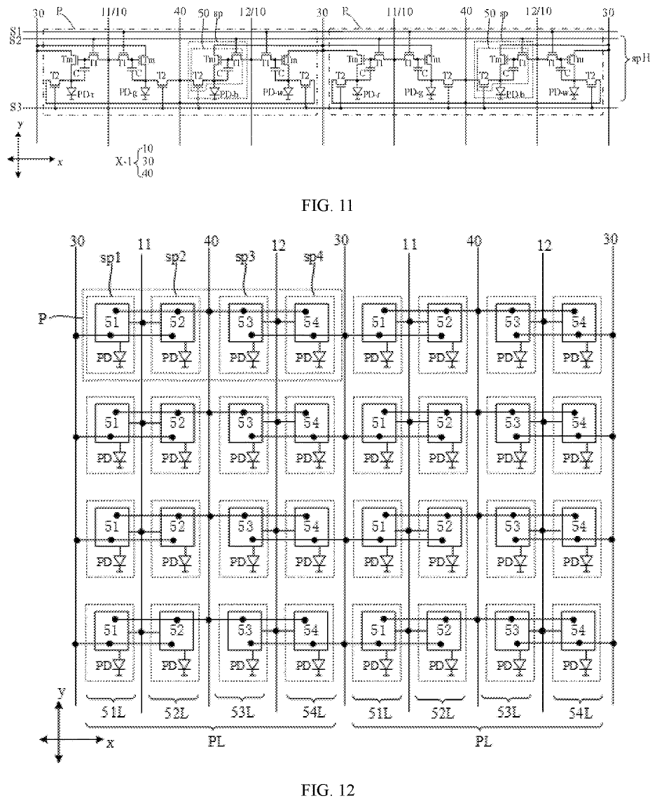

FIG. 12 is a schematic diagram of a display panel according to an embodiment of the present disclosure. The pixel circuit 50 is only simplified in FIG. 12, and the structure thereof may refer to the embodiment shown FIG. 3. FIG. 12 may be understood as a simplified structure of a portion in the display area in the embodiment shown FIG. 3. As shown in FIG. 12, the first sub-pixel sp1 includes a first pixel circuit 51, the second sub-pixel sp2 includes a second pixel circuit 52, the third sub-pixel sp3 includes a third pixel circuit 53, and the fourth sub-pixel sp4 includes a fourth pixel circuit 54. Multiple pixel units P are arranged in a pixel unit column PL in a first direction y, the pixel unit column PL includes a circuit unit column, the circuit unit column includes a first pixel circuit column 51L, a second pixel circuit column 52L, a third pixel circuit column 53L and a fourth pixel circuit column 54L sequentially arranged in a second direction x, and the second direction x intersects the first direction y; the first pixel circuit column 51L includes multiple first pixel circuits 51 arranged in the first direction y, the second pixel circuit column 52L includes multiple second pixel circuits 52 arranged in the first direction y, the third pixel circuit column 53L includes multiple third pixel circuits 53 arranged in the first direction y, and the fourth pixel circuit column 54L includes multiple fourth pixel circuits 54 arranged in the first direction y. FIG. 12 illustrates a signal line connection manner of two pixel unit columns PL in the display area AA.

In the signal lines connected to a same pixel unit column PL:
the first data line 11 is located between the first pixel circuit column 51L and the second pixel circuit column 52L adjacent to each other, and the second data line 12 is located between the third pixel circuit column 53L and the fourth pixel circuit column 54L; the first data line 11 is connected to pixel circuits in the first pixel circuit column 51L and the second pixel circuit column 52L, and the second data line 12 is connected to pixel circuits in the third pixel circuit column 53L and the fourth pixel circuit column 54L; and the reference signal line 40 is located between the second pixel circuit column 52L and the third pixel circuit column 53L, the reference signal line 40 is connected to four pixel circuit columns in the pixel unit column PL, one power-supply line 30 is located at a side of the first pixel circuit column 51L away from the second pixel circuit column 52L and connected to the first pixel circuit column 51L and the second pixel circuit column 52L, and the other power-supply line 30 is located at a side of the fourth pixel circuit column 54L away from the third pixel circuit column 53L and connected to the third pixel circuit column 53L and the fourth pixel circuit column 54L. It can be seen that the power-supply line 30 arranged between two adjacent pixel unit columns PL is connected to two pixel circuit columns of the two pixel unit columns PL located at the left and right sides thereof, that is, the power-supply line 30 is connected to four pixel circuit columns.

In some embodiments as shown in FIG. 12, the arrangement order of the signal lines connected to a same pixel unit P: a power-supply line 30, a first data line 11, a reference signal line 40, a second data line 12, and the power-supply line 30. As can be seen from FIG. 3, the arrangement order of the signal leads connected to a same pixel unit P is: a power-supply lead 22, a first data lead 211, a reference lead 23, a second data lead 212, and a power-supply lead 22. The arrangement order of the signal lines connected to a same pixel unit P and the arrangement order of the signal leads are the same.

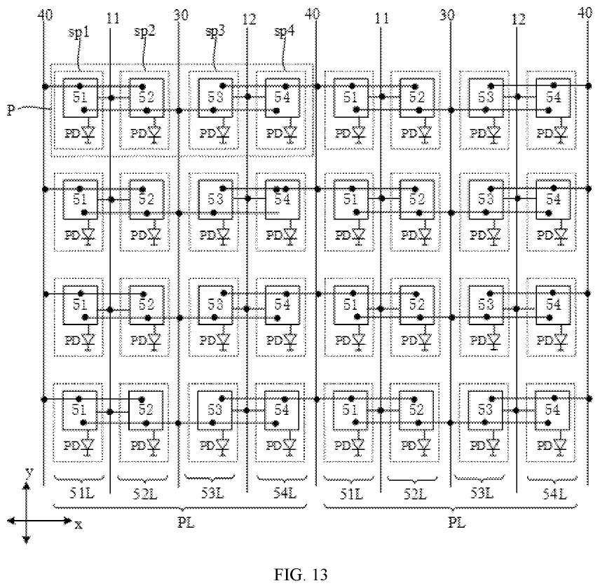

FIG. 13 is a schematic diagram of a display panel according to an embodiment of the present disclosure. As shown in FIG. 13, among the signal lines connected to a same pixel unit column PL:
the first data line 11 is located between the first pixel circuit column 51L and the second pixel circuit column 52L adjacent to each other, and the second data line 12 is located between the third pixel circuit column 53L and the fourth pixel circuit column 54L; the first data line 11 is connected to pixel circuits in the first pixel circuit column 51L and the second pixel circuit column 52L, and the second data line 12 is connected to pixel circuits in the third pixel circuit column 53L and the fourth pixel circuit column 54L; and
the power-supply line 30 is located between the second pixel circuit column 52L and the third pixel circuit column 53L, the power-supply line 30 is connected to four pixel circuit columns 50 in the pixel unit column P, one reference signal line 40 is located at a side of the first pixel circuit column 51L away from the second pixel circuit column 52L and connected to the first pixel circuit column 51L and the second pixel circuit column 52L, and the other reference signal line 40 is located at a side of the fourth pixel circuit column 54L away from the third pixel circuit column 53L and connected to the third pixel circuit column 53L and the fourth pixel circuit column 54L. It can be seen that the reference signal line 40 arranged between two adjacent pixel unit columns PL is connected to two pixel circuit columns in the two pixel unit columns PL located at the left and right sides thereof, that is, the reference signal line 40 is connected to four pixel circuit columns.

In some embodiments of FIG. 13, the arrangement order of the signal lines connected to a same pixel unit P is: a reference signal line 40, a first data line 11, a power-supply line 30, a second data line 12, and a reference signal line 40 in sequence. Referring to FIG. 3, it is understood that the signal lines in the display area AA and the signal leads in the non-display area NA are sequentially connected to each other, and the arrangement order of the signal leads connected to a same pixel unit P is: a reference lead 23, a first data lead 211, a power-supply lead 22, a second data lead 212, and a reference lead 23. The arrangement order of the signal lines connected to a same pixel unit P, and the arrangement order of the signal leads are the same.

The first scan line S1, the second scan line S2 and the third scan line S3 shown in FIG. 3 also need to be arranged in some embodiments shown in FIG. 12 and FIG. 13. The sub-pixel rows in FIG. 12 and FIG. 13 are driven by using the timing sequence provided in FIG. 4.

In some embodiments shown in FIG. 12, except that the first power-supply line 30 and the last power-supply line 30 at the edge of the display area respectively drive two pixel circuit columns, the remaining power-supply lines 30 drive four pixel circuit columns respectively, and one reference signal line 40 drives four pixel circuit columns. In some embodiments shown in FIG. 13, except that the first reference signal line 40 and the last reference signal line 40 at the edge of the display area respectively drive two pixel circuit columns, the remaining reference signal lines 40 drive four pixel circuit columns, respectively, and one power-supply line 30 drives four pixel circuit columns. In some embodiments shown in FIG. 12 and FIG. 13, the power-supply line 30 or the reference signal line 40 can be arranged between the adjacent first data line 11 and second data line 12, so that when the signal leads in the non-display area NA are sequentially connected to the signal lines in the display area AA, the power-supply lead 22 or the reference lead 23 is arranged between the first data lead 211 and second data lead 212 adjacent to each other. Therefore, during the display period, the power-supply lead 22 or the reference lead 23 can be used to perform signal shielding between the adjacent first data lead 211 and second data lead 212, thereby reducing signal crosstalk between the first data lead 211 and the second data lead 212 that transmit a high-frequency data voltage, improving accuracy of data voltage transmission on the data lead 21, and improving display quality.

Moreover, in some embodiments shown in FIG. 12 and FIG. 13, the number of the sub-pixel columns connected to one power-supply line 30 is not too large, so that the power voltage received by each sub-pixel sp is relatively uniform, and the number of the power-supply lines 30 arranged in the display area AA can also be reduced, thereby improving the display aperture ratio.

In some embodiments shown in FIG. 12 and FIG. 13, the number of sub-pixel columns connected to one reference signal line 40 is not too large, the sensing signal collected by using the reference signal line 40 in the compensation mode will be relatively accurate, and correspondingly, the reference voltage received by each sub-pixel sp in the display mode will also be relatively uniform.

In addition, in some embodiments shown in FIG. 12, one reference signal line 40 is connected to four pixel circuit columns. In some embodiments shown in FIG. 13, except for the first reference signal line 40 and the last reference signal line 40 at the edge of the display area, the remaining reference signal lines 40 drive four pixel circuit columns, respectively. That is, in FIG. 12, each reference signal line 40 is shared by four sub-pixel columns, and in some embodiments shown in FIG. 13, most of the reference signal lines 40 are shared by four sub-pixel columns. Therefore, the number of the reference signal lines 40 arranged in the display area AA can be reduced, thereby improving the display aperture ratio. Moreover, the number of the reference leads 23 arranged in the non-display area NA can be reduced, and the number of the contacts directly connected to the data driving integrated circuit (i.e., the circuit for receiving the sensing signal in the compensation mode and generating the compensated data voltage according to the sensing signal) in the display driving chip can also be reduced, which is beneficial to reducing the manufacturing cost of the display driving chip.

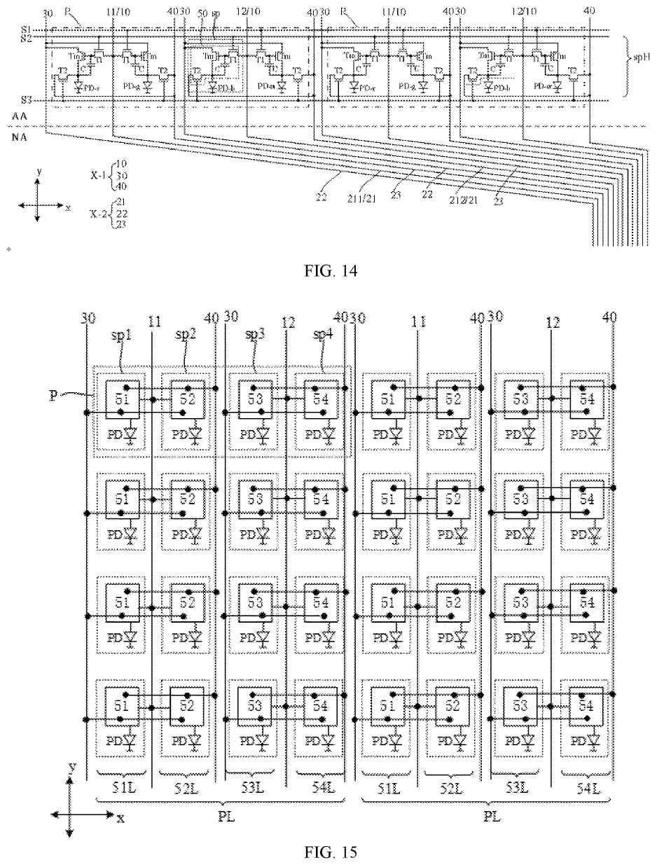

FIG. 14 is a schematic diagram of a display panel according to an embodiment of the present disclosure. As shown in FIG. 14, a first sub-pixel, a second sub-pixel, a third sub-pixel and a fourth sub-pixel of different colors are arranged in a second direction x to form a pixel unit P. In FIG. 14, as an example, the first sub-pixel includes a red light-emitting device PD-r, the second sub-pixel includes a green light-emitting device PD-g, the third sub-pixel includes a blue light-emitting device PD-b, and the fourth sub-pixel includes a white light-emitting device PD-w. The arrangement order of the signal leads X-2 connected to a same pixel unit P is: a power-supply lead 22, a first data lead 211, a reference lead 23, a power-supply lead 22, a second data lead 212, and a reference lead 23.

In some embodiments, the positions of the power-supply line 30 and the reference signal line 40 in the display area AA in FIG. 14 are exchanged, and the positions of the power-supply lead 22 and the reference lead 23 in the non-display area NA are exchanged, so that the arrangement order of the signal leads X-2 connected to a same pixel unit P is: a reference lead 23, a first data lead 211, a power-supply lead 22, a reference lead 23, a second data lead 212, and a power-supply lead 22, which will not be illustrated with accompanied drawings herein.

According to the embodiments shown in FIG. 14, it can be realized that one power-supply lead 22 and one reference lead 23 are provided between the first data lead 211 and the second data lead 212 adjacent to each other. During the display period, the power-supply lead 22 and the reference lead 23 are used to perform signal shielding between the adjacent first data lead 211 and second data lead 212, thereby reducing signal crosstalk between the first data lead 211 and the second data lead 212 that transmit a high-frequency data voltage, improving accuracy of data voltage transmission on the data lead 21, and improving display quality.

In addition, as can be seen from FIG. 14, the arrangement order of the signal lines X-1 connected to a same pixel unit P in this embodiment is the same as the arrangement order of the signal leads X-2. That is, the signal lines X-1 in the display area AA are sequentially connected to the signal leads X-2 in the non-display area NA.

FIG. 15 is a schematic diagram of a display panel according to an embodiment of the present disclosure. The pixel circuit 50 is merely simplified in FIG. 15, and the structure thereof may refer to the embodiment shown in FIG. 3. As shown in FIG. 15, the first sub-pixel sp1 includes a first pixel circuit 51, the second sub-pixel sp2 includes a second pixel circuit 52, the third sub-pixel sp3 includes a third pixel circuit 53, and the fourth sub-pixel sp4 includes a fourth pixel circuit 54. Multiple pixel units P are arranged in a pixel unit column PL in a first direction y, the pixel unit column PL includes a circuit unit column, the circuit unit column includes a first pixel circuit column 51L, a second pixel circuit column 52L, a third pixel circuit column 53L and a fourth pixel circuit column 54L sequentially arranged in a second direction x, and the second direction x intersects the first direction y; the first pixel circuit column 51L includes multiple first pixel circuits 51 arranged in the first direction y, the second pixel circuit column 52L includes multiple second pixel circuits 52 arranged in the first direction y, the third pixel circuit column 53L includes multiple third pixel circuits 53 arranged in the first direction y, and the fourth pixel circuit column 54L includes multiple fourth pixel circuits 54 arranged in the first direction y. FIG. 12 illustrates a signal line connection manner of two pixel unit columns PL in the display area AA.

In the signal lines connected to a same pixel unit column PL:
the first data line 11 is located between the adjacent first pixel circuit column 51L and the second pixel circuit column 52L, and the second data line 12 is located between the third pixel circuit column 53L and the fourth pixel circuit column 54L; and the first data line 11 connects the pixel circuits in the first pixel circuit column 51L and in the second pixel circuit column 52L, and the second data line 12 connects the pixel circuits in the third pixel circuit column 53L and in the fourth pixel circuit column 54L.

One reference signal line 40 is located between the second pixel circuit column 52L and the third pixel circuit column 53L and connected to the first pixel circuit column 51L and the second pixel circuit column 52L, another reference signal line 40 is located at a side of the fourth pixel circuit column 54L away from the third pixel circuit column 53L and connected to the third pixel circuit column 53L and the fourth pixel circuit column 54L, one power supply line 30 is located on a side of the first pixel circuit column 51L away from the second pixel circuit column 52L and connected to the first pixel circuit column 51L and the second pixel circuit column 52L, and another power supply line 30 is located between and connected to the third pixel circuit column 53L and the fourth pixel circuit column 54L. Alternatively, the positions of the power-supply line 30 and the reference signal line 40 are interchanged in FIG. 15. One power-supply line 30 is located between the second pixel circuit column 52L and the third pixel circuit column 53L and connected to the first pixel circuit column 51L and the second pixel circuit column 52L, the other power-supply line 30 is located on a side of the fourth pixel circuit column 54L away from the third pixel circuit column 53L and connected to the third pixel circuit column 53L and the fourth pixel circuit column 54L, one reference signal line 40 is located at a side of the first pixel circuit column 51L away from the second pixel circuit column 52L and connected to the first pixel circuit column 51L and the second pixel circuit column 52L, and the other reference signal line 40 is located between the second pixel circuit column 52L and the third pixel circuit column 53L and connected to the third pixel circuit column 53L and the fourth pixel circuit column 54L, which will not be illustrated with accompanied drawings herein.

In some embodiments shown in FIG. 15, the arrangement order of the signal lines connected to a same pixel unit P is: the power-supply line 30, the first data line 11, the reference signal line 40, the power-supply line 30, and the second data line 12. The arrangement order of the reference signal line 40 is: a power-supply lead 22, a first data lead 211, a reference lead 23, a power-supply lead 22, a second data lead 212, and a reference lead 23. The arrangement order of the signal lines connected to a same pixel unit P and the arrangement order of the signal leads are the same.

In some embodiments shown in FIG. 15, the first scan line S1, the second scan line S2 and the third scan line S3 shown in FIG. 3 need to be arranged. The sub-pixel rows extending along the second direction x in FIG. 15 may be driven by using the timing sequence provided in FIG. 4.

By adopting the design of the embodiment shown in FIG. 15, it can be realized that a power-supply line 30 and a reference signal line 40 can be arranged between the first data line 11 and the second data line 12 adjacent to each other, so that when the signal leads in the non-display area NA are sequentially connected to the signal lines in the display area AA, a power-supply lead 22 and a reference lead 23 are arranged between the first data lead 211 and the second data lead 212 adjacent to each other. Therefore, during the display period, the power-supply lead 22 and the reference lead 23 can be used to perform signal shielding between the adjacent first data lead 211 and second data lead 212, thereby reducing signal crosstalk between the first data lead 211 and the second data lead 212 that transmit a high-frequency data voltage, improving accuracy of data voltage transmission on the data lead 21, and improving display quality.

Moreover, in some embodiments shown in FIG. 15, one power-supply line 30 drives two pixel circuit columns, that is, one power-supply line 30 is connected to two sub-pixel columns. In other words, two sub-pixel columns share one power-supply line 30. If the number of sub-pixel columns connected to one power-supply line 30 is not too large, the power voltage received by each sub-pixel sp is relatively uniform. Sharing the power-supply lines 30 can also reduce the number of the power-supply lines 30 arranged in the display area AA, thereby facilitating improving the display aperture ratio.

In some embodiments shown in FIG. 15, one reference signal line 40 drives two pixel circuit columns, that is, one reference signal line 40 is connected to two sub-pixel columns. In other words, two sub-pixel columns share one reference signal line 40. The number of sub-pixel columns connected to one reference signal line 40 is not too large, the sensing signal collected by the reference signal line 40 in the compensation mode will be relatively accurate, and the corresponding reference voltage received by each sub-pixel sp in the display mode is also relatively uniform. Sharing the reference signal lines 40 can also reduce the number of the reference signal lines 40 arranged in the display area AA, thereby facilitating improving the display aperture ratio. Moreover, the number of the reference leads 23 arranged in the non-display area NA can be reduced, and the number of the contacts directly connected to the data driving integrated circuit in the display driving chip is also reduced, thereby facilitating reducing the manufacturing cost of the display driving chip.

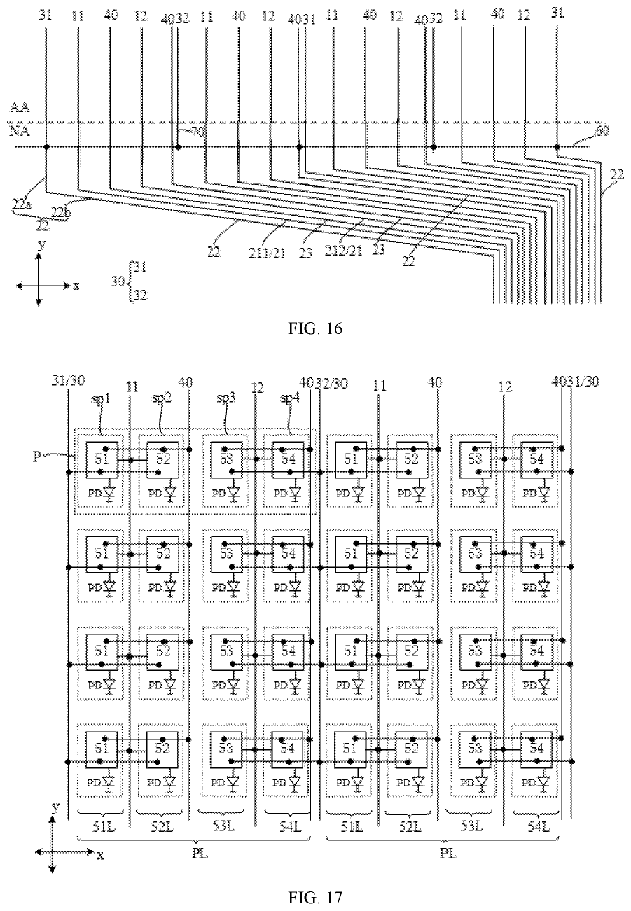

FIG. 16 is a schematic diagram of a display panel according to an embodiment of the present disclosure. As shown in FIG. 16, the display area AA includes a power-supply line 30, a data line 10, and a reference signal line 40 extending along the first direction y, the data line 10 includes a first data line 11 and a second data line 12 adjacent to each other, the first data line 11 is connected to two sub-pixels with different colors, and the second data line 12 is connected to two sub-pixels with different colors. The power-supply line 30 includes a first power-supply line 31 and a second power-supply line 32. The non-display area NA includes a data lead 21, a power-supply lead 22 and a reference lead 23, and the data lead 21 includes a first data lead 211 connected to the first data line 11 and a second data lead 212 connected to the second data line 12. The reference leads 23 are connected to the reference signal lines 40 in one-to-one correspondence.

The power-supply lead 22 includes a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y. The non-display area NA further includes a power-supply bus 60 extending along the second direction x and a connection line 70 extending along the first direction y. The power-supply lead 22 is connected to the power-supply bus 60, the first power-supply line 31 is connected to the power-supply lead 22, one end of the connection line 70 is connected to the second power-supply line 32, and the other end of the connection line 70 is connected to the power-supply bus 60. One reference lead 23 is disposed between two adjacent data leads 21, n data leads 21 and n reference leads 23 are spaced between two adjacent power-supply leads 22, where n is an integer, and 2≤n≤6. FIG. 16 illustrates n=4.

In this embodiment, a reference lead 23 is disposed between the first data lead 211 and the second data lead 212 adjacent to each other, and one power-supply lead 22 is disposed apart from n data leads 21 and n reference leads 23. Therefore, as a whole, a reference lead 23 is disposed between a part of first data leads 211 and second data leads 212 adjacent to each other, and a reference lead 23 and a power-supply lead 22 are disposed between a part of first data leads 211 and second data leads 212 adjacent to each other. In the display period, the reference lead 23 and the power-supply lead 22 can shield signals to reduce signal crosstalk between the first data lead 211 and the second data lead 212 that transmit a high-frequency data voltage.

In addition, in the display area AA, the first power-supply line 31 is connected to the power-supply lead 22, the power-supply lead 22 is connected to the power-supply bus 60, and the second power-supply line 32 is connected to the power-supply bus 60 through the connection wire 70. The power-supply bus 60 provides the power voltage to the second power-supply line 32 in the display area AA, and the power-supply bus 60 can balance the voltage drop difference between the first power-supply line 31 and the second power-supply line 32, thereby improving the power voltage uniformity in the display area AA.

In some embodiments, multiple sub-pixels include a first sub-pixel sp1, a second sub-pixel sp2, a third sub-pixel sp3 and a fourth sub-pixel sp4 having different colors; the first sub-pixel sp1, the second sub-pixel sp2, the third sub-pixel sp3 and the fourth sub-pixel sp4 are arranged in the second direction x to form a pixel unit P; and the first sub-pixel sp1 includes a first pixel circuit 51, the second sub-pixel sp2 includes a second pixel circuit 52, the third sub-pixel sp3 includes a third pixel circuit 53, and the fourth sub-pixel sp4 includes a fourth pixel circuit 54.

Multiple pixel units P are arranged in a pixel unit column PL in the first direction y, the pixel unit column PL includes circuit unit columns, the circuit unit columns include a first pixel circuit column 51L, a second pixel circuit column 52L, a third pixel circuit column 53L and a fourth pixel circuit column 54L sequentially arranged in the second direction x. The first pixel circuit column 51L includes multiple first pixel circuits 51 arranged in the first direction y, the second pixel circuit column 52L includes multiple second pixel circuits 52 arranged in the first direction y, the third pixel circuit column 53L includes multiple third pixel circuits 53 arranged in the first direction y, and the fourth pixel circuit column 54L includes multiple fourth pixel circuits 54 arranged in the first direction y.

FIG. 17 is a schematic diagram of a display panel according to an embodiment of the present disclosure. The pixel circuit 50 is merely simplified in FIG. 17, and the structure thereof may refer to the embodiment shown in FIG. 3. FIG. 17 illustrates a connection manner of the signal lines of two pixel unit columns PL in the display area AA. As shown in FIG. 17, among the signal lines connected to a same pixel unit column PL: the first data line 11 is located between the first pixel circuit column 51L and the second pixel circuit column 52L adjacent to each other, and the second data line 12 is located between the third pixel circuit column 53L and the fourth pixel circuit column 54L; the first data line 11 is connected to the pixel circuits in the first pixel circuit column 51L and the second pixel circuit column 52L, and the second data line 12 is connected to the pixel circuits in the third pixel circuit column 53L and the fourth pixel circuit column 54L. One reference signal line 40 is located between the second pixel circuit column 52L and the third pixel circuit column 53L and connected to the second pixel circuit column 52L and the first pixel circuit column 51L, and the other reference signal line 40 is located at a side of the fourth pixel circuit column 54L away from the third pixel circuit column 53L and connected to the fourth pixel circuit column 54L and the third pixel circuit column 53L. One power-supply line 30 is located at a side of the first pixel circuit column 51L away from the second pixel circuit column 52L and is connected to the first pixel circuit column 51L and the second pixel circuit column 52L; the other power-supply line 30 is located at a side of the fourth pixel circuit column 54L away from the third pixel circuit column 53L and is connected to the fourth pixel circuit column 54L and the third pixel circuit column 53L. In this embodiment, one reference signal line 40 is connected to two pixel circuit columns, and except that the first and last power-supply lines 30 arranged in the display area are connected to two pixel circuit columns, the remaining power-supply lines 30 are respectively connected to four pixel circuit columns.

In some embodiments shown in FIG. 17, signal line wiring at positions of two pixel unit columns PL is illustrated, and in combination with the wiring mode in the non-display NA in FIG. 16, when n=4, three power-supply lines 30 are illustrated in FIG. 17, in which the first power-supply line 30 and the last power-supply line 30 are the first power-supply lines 31, and the power-supply line 30 arranged at the middle position is the second power-supply line 32.

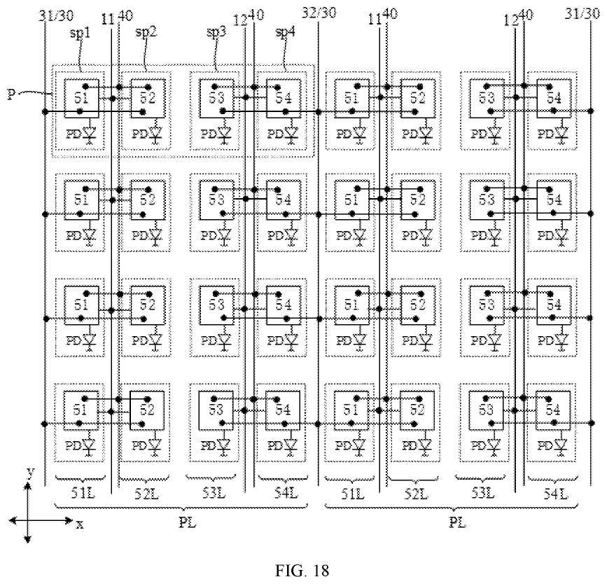

FIG. 18 is a schematic diagram of a display panel according to an embodiment of the present disclosure. FIG. 18 illustrates a connection manner of the signal lines of two pixel unit columns PL in a display area AA. FIG. 18 differs from the embodiment shown in FIG. 17 in the arrangement positions of the power-supply line 30 and the reference signal line 40. As shown in FIG. 18, among the signal lines connected to a same pixel unit column PL: one reference signal line 40 is located between the first pixel circuit column 51L and the second pixel circuit column 52L and connected to the first pixel circuit column 51L and the second pixel circuit column 52L; another reference signal line 40 is located between the third pixel circuit column 53L and the fourth pixel circuit column 54L and connected to the third pixel circuit column 53L and the fourth pixel circuit column 54L; one power-supply line 30 is located at a side of the first pixel circuit column 51L away from the second pixel circuit column 52L and connected to the first pixel circuit column 51L and the second pixel circuit column 52L; and another power-supply line is located at a side of the fourth pixel circuit column 54L away from the third pixel circuit column 53L and connected to the third pixel circuit column 53L and the fourth pixel circuit column 54L. In this embodiment, one reference signal line 40 is connected to two pixel circuit columns, and except that the first and last power-supply lines 30 arranged in the display area are connected to two pixel circuit columns, the remaining power-supply lines 30 are respectively connected to four pixel circuit columns.

In some embodiments as shown in FIG. 18, signal line wiring at positions of two pixel unit columns PL is illustrated, and in combination with the wiring mode in the non-display NA in FIG. 16, when n=4, three power-supply lines 30 are illustrated in FIG. 18, in which the first power-supply line 30 and the last power-supply line 30 are the first power-supply lines 31, and the power-supply line 30 arranged at the middle position is the second power-supply line 32.

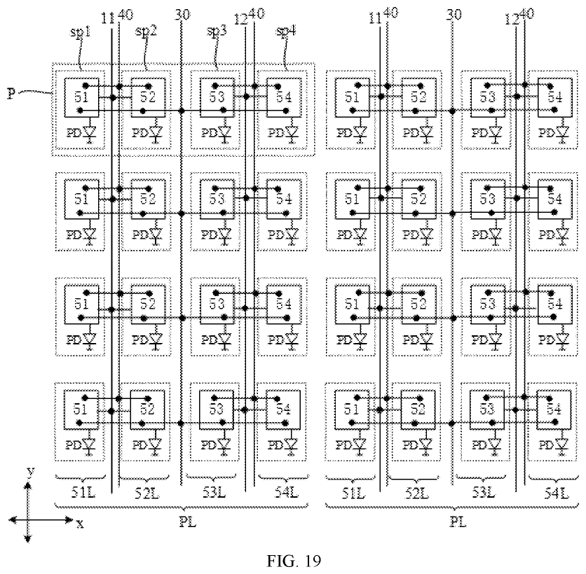

FIG. 19 is a schematic diagram of a display panel according to an embodiment of the present disclosure. FIG. 19 illustrates a connection manner of the signal lines of two pixel unit columns PL in a display area AA. FIG. 19 differs from the embodiment shown in FIG. 17 in the arrangement positions of the power-supply line 30 and the reference signal line 40. As shown in FIG. 19, among the signal lines connected to a same pixel unit column PL: one reference signal line 40 is located between the first pixel circuit column 51L and the second pixel circuit column 52L and connected to the first pixel circuit column 51L and the second pixel circuit column 52L; another reference signal line 40 is located between the third pixel circuit column 53L and the fourth pixel circuit column 54L and connected to the third pixel circuit column 53L and the fourth pixel circuit column 54L; and a power supply line 30 is located between the second pixel circuit column 52L and the third pixel circuit column 53L and connected to the four pixel circuit columns. In this embodiment, one reference signal line 40 is connected to two pixel circuit columns, and one power-supply line 30 is connected to four pixel circuit columns.

In some embodiments as shown in FIG. 19, the power-supply lines 30 in the display area may also be divided into first power-supply lines 31 and second power-supply lines 32, and referring to the wiring manner of the signal leads in the non-display area NA in FIG. 16, the first power-supply line 31 is connected to the power-supply lead 22, the power-supply lead 22 is connected to the power-supply bus 60, and the second power-supply line 32 is connected to the power-supply bus 60 through the connection line 70.

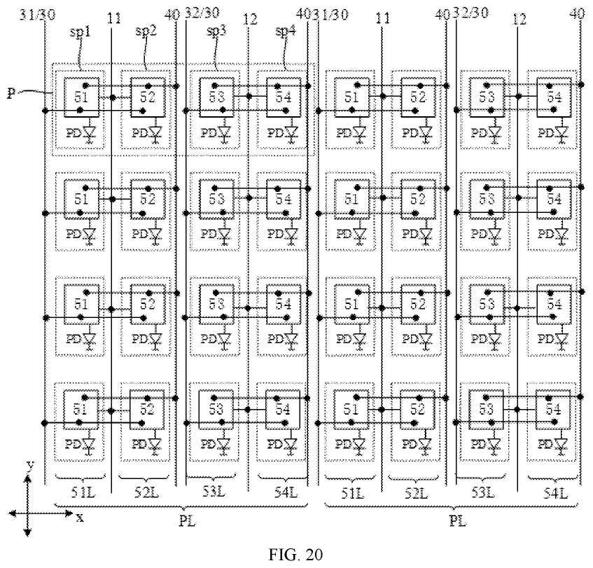

FIG. 20 is a schematic diagram of a display panel according to an embodiment of the present disclosure. FIG. 20 illustrates a connection manner of the signal lines of two pixel unit columns PL in a display area AA. FIG. 20 differs from the embodiment shown in FIG. 17 in the arrangement positions of the power-supply line 30 and the reference signal line 40. As shown in FIG. 20, among the signal lines connected to a same pixel unit column PL: one reference signal line 40 and one power-supply line 30 are located between the second pixel circuit column 52L and the third pixel circuit column 53L; and another power-supply line 30 and another reference signal line 40 are respectively arranged at a side of the fourth pixel circuit column 54L away from the third pixel circuit column 53L and at a side of the first pixel circuit column 51L away from the second pixel circuit column 52L. In this embodiment, one reference signal line 40 is connected to two pixel circuit columns, and one power-supply line 30 is connected to two pixel circuit columns.

In some embodiments as shown in FIG. 20, multiple power-supply lines 30 in the display area may also be divided into first power-supply lines 31 and second power-supply lines 32, and referring to the wiring manner of the signal leads in the non-display area NA in FIG. 16, the first power-supply line 31 is connected to the power-supply lead 22, the power-supply lead 22 is connected to the power-supply bus 60, and the second power-supply line 32 is connected to the power-supply bus 60 through the connection line 70. For example, four power-supply lines 30 are illustrated in FIG. 20, setting n=2, the first one and the third one of the power-supply lines are the first power-supply lines 31, and the second one and the fourth one of the power-supply lines 30 are the second power-supply lines 32.

In some embodiments as shown in FIG. 17 to FIG. 20, the wiring of the signal lines in the display area AA is illustrated, and the wiring of the signal leads in the non-display area corresponding to the embodiments shown in FIG. 17 to FIG. 20 may adopt the design of the embodiment shown in FIG. 16.

In the design idea in some embodiments shown in FIG. 16, a reference lead 23 is arranged between adjacent first data leads 211 and second data leads 212, and meanwhile, a power-supply lead 22 is arranged apart from n data leads 21 and n reference leads 23. The DGLD technology can reduce the number of data lines in the display area and thus reduce the number of data leads in the non-display area. By applying the design idea in some embodiments shown in FIG. 16 to the display panel using the DGLD technology, it can be understood that there is a relatively ample space in the non-display area to arrange the signal leads, so that the line widths of the signal leads can be appropriately adjusted. For example, the line width of the data lead 21 is d1, the line width of the power-supply lead 22 is d2, and d1≤d2≤10*d1. By increasing the line width of the power-supply lead 22, the voltage drop across the power-supply lead 22 can be reduced, and the uniformity of power-supply voltage transmission can be improved.

In some embodiments, as shown in FIG. 7 or FIG. 8A, the line width of the power-supply lead 22 is greater than the line width of the data lead 21. The power-supply lead 22 includes a first line segment 22a and a second line segment 22b, the first line segment 22a is connected between the power-supply line 30 and the second line segment 22b, the first line segment 22a extends along the first direction y, and an acute angle is formed between the extending direction of the second line segment 22b and the first direction y. The data lead 21 includes a fifth line segment 21a and a sixth line segment 21b, the fifth line segment 21a is connected between the data line 10 and the sixth line segment 21b, the fifth line segment 21a extends along the first direction y, and an acute angle is formed between the extending direction of the sixth line segment 21b and the first direction y. Comparing the first line segment 22a and the fifth line segment 21a extending in a same direction, or comparing the second line segment 22b and the sixth line segment 21b that are oblique line segments, the line width of the power-supply lead 22 is greater than the line width of the data lead 21. By providing the power-supply lead 22 with a relatively large line width, the impedance of the power-supply lead 22 can be reduced, thereby reducing the voltage drop across the power-supply lead 22 and improving the uniformity of power-supply voltage transmission. With reference to the DGLD technology in the present disclosure, in the display panel using the DGLD technology, the number of the data leads 21 in the non-display area is halved, so that sufficient space can be provided to meet the design of the line width of the power-supply lead 22.

In some embodiments, the line width of the data lead 21 is d1, the line width of the power-supply lead 22 is d2, and d1=d2. That is, the line widths of the data lead 21 and the power-supply lead 22 are not designed differently, which reduces the space occupied by the arrangement of the signal leads in the non-display area and narrows the frame.

As shown in FIG. 7, a line width of the data lead 21 is d1, a line width of the power-supply lead 22 is d2, and d1<d2≤5*d1. When the line width of the power-supply lead 22 is designed, two factors, the voltage drop of the power and the layout space of the non-display area, are considered at the same time, and by setting d2>d1, the voltage drop of the transmitted power voltage can be reduced and the display uniformity can be improved. Meanwhile, d2 cannot be set to be too large, so that the space occupied by the arrangement of the signal leads can be prevented from being affected.

In some embodiments, the line width of the reference lead 23 is equal to the line width of the data lead 21. The line widths of the two leads are the same. When the two leads are located in a same metal layer, the etching uniformity can be improved during manufacturing, and the error between the line width of the lead obtained by the etching process and the design value can be reduced.

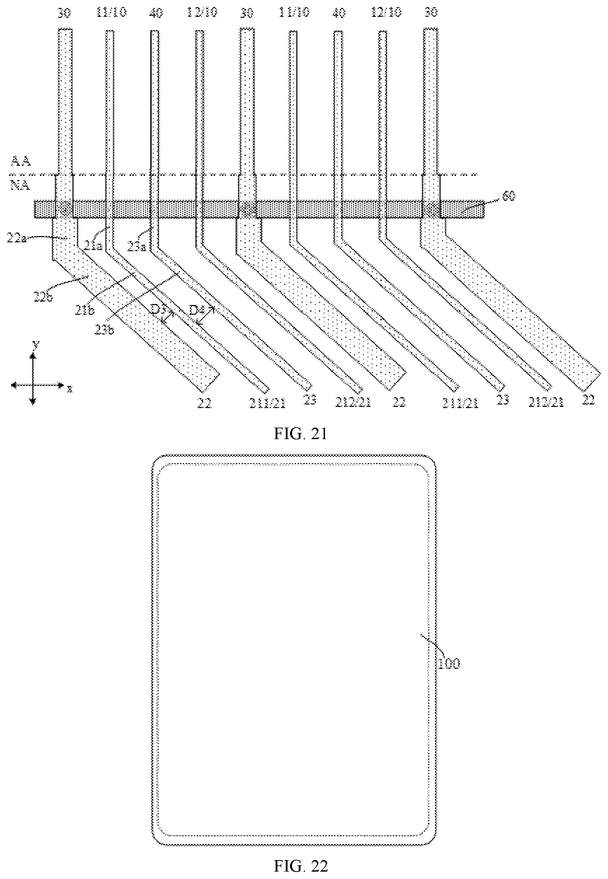

FIG. 21 is a schematic diagram of a display panel according to an embodiment of the present disclosure. As shown in FIG. 21, the display area AA includes a power-supply line 30, a reference signal line 40, a first data line 11 and a second data line 12. The first data line 11 is connected to the first data lead 211, and the second data line 12 is connected to the second data lead 212. The power-supply lead 22 includes a first line segment 22a and a second line segment 22b, the first line segment 22a is connected between the power-supply line 30 and the second line segment 22b, the first line segment 22a extends along the first direction y, and an acute angle is formed between an extending direction of the second line segment 22b and the first direction y. The reference lead 23 includes a third line segment 23a and a fourth line segment 23b, the third line segment 23a is connected between the reference signal line 40 and the reference lead 23, the third line segment 23a extends along the first direction y, and the fourth line segment 23b and the second line segment 22b extend in a same direction. The data lead 21 includes a fifth line segment 21a and a sixth line segment 21b, the fifth line segment 21a is connected between the data line 10 and the sixth line segment 21b, the fifth line segment 21a extends along the first direction y, and the sixth line segment 21b and the second line segment 22b extend in a same direction. A distance between the second line segment 22b and the sixth line segment 21b adjacent to each other is D3, and a distance between the fourth line segment 23b and the sixth line segment 21b adjacent to each other is D4, where D3<D4.

In this embodiment, the second line segment 22b of the power-supply lead 22, the fourth line segment 23b of the reference lead 23, and the sixth line segment 21b of the data lead 21 are all oblique line segments. The signal leads are configured to have an oblique segment, so that the signal leads are led out from the boundary position of the display area AA and the non-display area NA, then are gathered to be arranged in a fan-shaped arrangement, and finally extend to the position of the signal terminal (configured to be connected to the display driving chip). With reference to the description of the working principle of the pixel circuit in the foregoing embodiments, it should be known that the power-supply lead 22 provides a constant voltage signal to the power-supply line 30 in both the compensation mode and the display mode of the pixel circuit, and the reference lead 23 is used to transmit the sensing signal collected by the reference signal line 40 in the compensation mode of the pixel circuit, and provide a constant voltage signal to the reference signal line 40 in the display mode of the pixel circuit. In some embodiments of the present disclosure, the distance between the second line segment 22b and the sixth line segment 21b adjacent to each other is smaller than the distance between the fourth line segment 23b and the sixth line segment 21b adjacent to each other. That is, the distance between the power-supply lead 22 and the data lead 21 adjacent to each other in the oblique line segment is shorter. By differently setting the spacing between adjacent signal leads of different functions, the shielding capability of the power-supply lead 22 on the high-frequency data voltage on the data lead 21 can be enhanced at the position where the power-supply lead 22 is set, thereby effectively reducing signal crosstalk.

Exemplarily, the line width of the power-supply lead 22 is greater than the spacing between the power-supply lead 22 and the data lead 21 adjacent thereto. Under the condition that the space arrangement requirement is met, the width of the power-supply lead 22 is manufactured to be greater. On the one hand, the voltage drop of the transmitted power-supply voltage can be reduced; on the other hand, the spacing between the data leads 21 on the left and right sides of the power-supply lead 22 can be increased, facilitating reducing the signal crosstalk between the data leads 21.

Exemplarily, the line width of the power-supply lead 22 is greater than the spacing between the data lead 21 and the reference lead 23 adjacent thereto. Under the condition that the space arrangement requirement is met, the width of the power-supply lead 22 is greater, which can reduce the voltage drop of the transmitted power-supply voltage.

Based on the same inventive concept, the present disclosure further provides a display apparatus. FIG. 22 is a schematic diagram of a display apparatus according to an embodiment of the present disclosure. As shown in FIG. 22, the display apparatus includes the display panel 100 according to any embodiment of the present disclosure. The structure of the display panel 100 has been described in the foregoing embodiments, which will not be repeated herein. The display apparatus according to some embodiments of the present disclosure may be, for example, an electronic device having a display function, such as a mobile phone, a tablet, a computer, a television, and a smart wearable product.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising a display area and a non-display area, wherein
the display area comprises sub-pixels and data lines extending along a first direction, the data lines comprise first data lines and second data lines, one of the first data lines is adjacent to one of the second data lines, one of the first data lines is connected to two of the sub-pixels with different colors, and one of the second data lines is connected to two sub-pixels with different colors; and
the non-display area comprises data leads, power-supply leads, and reference leads, the data leads comprise first data leads and second data leads, the first data leads are connected to the first data lines, and the second data leads are connected to the second data lines, wherein one of the power-supply leads and/or one of the reference leads are arranged between one of the first data leads and one of the second data leads that are adjacent to each other.

2. The display panel according to claim 1, wherein
the display area comprises power-supply lines and reference signal lines that extend along the first direction, the power-supply lines are connected to the power-supply leads, and the reference signal lines are connected to the reference leads;
one of the sub-pixels comprises a light emitting device and a pixel circuit, and the pixel circuit comprises a driving transistor, a first switching transistor, a second switching transistor and a storage capacitor; and
a control terminal of the driving transistor is connected to a first node, a first electrode of the driving transistor is connected to one of the power-supply lines, a second electrode of the driving transistor is connected to a second node, a first electrode of the first switching transistor is connected to one of the data lines, a second electrode of the first switching transistor is connected to the first node, a first electrode of the second switching transistor is connected to one of the reference signal lines, a second electrode of the second switching transistor is connected to the second node, one plate of the storage capacitor is connected to the first node, and the other plate of the storage capacitor is connected to the second node.

3. The display panel according to claim 1, wherein
the display area comprises power-supply lines and reference signal lines that extend along the first direction, the power-supply lines are connected to the power-supply leads, and the reference signal lines are connected to the reference leads; and
the power-supply line and/or the reference signal line are arranged between one of the first data lines and one of the second data lines that are adjacent to each other.

4. The display panel according to claim 1, wherein
the display area comprises power-supply lines extending along the first direction; one of the power-supply leads comprises a first line segment and a second line segment, the first line segment is connected between one of the power-supply lines and the second line segment, the first line segment extends along the first direction, and an acute angle is formed between an extending direction of the second line segment and the first direction; and the power-supply lines are connected to the power-supply leads in one-to-one correspondence; and/or the display area comprises reference signal lines extending along the first direction; one of the reference leads comprises a third line segment and a fourth line segment, the third line segment is connected between one of the reference signal lines and the fourth line segment, the third line segment extends along the first direction, and an acute angle is formed between an extending direction of the fourth line segment and the first direction; and the reference signal lines are connected to the reference leads in one-to-one correspondence.

5. The display panel according to claim 4, wherein
a spacing between two adjacent power-supply lines is D1, and a spacing between two first line segments of two adjacent power-supply leads is D2, where D1>D2.

6. The display panel according to claim 1, wherein
the display area comprises power-supply lines extending along the first direction, one of the power-supply leads comprises a first line segment and a second line segment, the first line segment is connected between one of the power-supply lines and the second line segment, the first line segment extends along the first direction, and an acute angle is formed between an extending direction of the second line segment and the first direction; and
the first line segment comprises a first sub-segment and a second sub-segment, and the second sub-segment is connected between the first sub-segment and the second line segment, wherein a spacing between two adjacent second sub-segments is less than a spacing between two adjacent first sub-segments.

7. The display panel according to claim 6, wherein a width of the second sub-segment is greater than a width of the first sub-segment; or
wherein the non-display area comprises a power-supply bus extending in a second direction, and the second direction intersects the first direction, and the power-supply bus is electrically connected to the power-supply leads, wherein the second sub-segment is located at a side of the power-supply bus away from the display area.

8. The display panel according to claim 1, wherein
the sub-pixels comprises first sub-pixels, second sub-pixels, third sub-pixels and fourth sub-pixels that have different colors from one another; and one of the first sub-pixels, one of the second sub-pixels, one of the third sub-pixels and one of the fourth sub-pixels constitute a pixel unit;
the display area comprises power-supply lines and reference signal lines that extend along the first direction, the power-supply lines are connected to the power-supply leads, and the reference signal lines are connected to the reference leads;
the display panel comprises signal lines located in the display area and signal leads located in the non-display area, the signal lines comprise the data lines, the power-supply lines and the reference signal lines, and the signal leads comprise the data leads, the power-supply leads and the reference leads; and
the signal lines connected to a same pixel unit have a same arrangement order as the signal leads.

9. The display panel according to claim 8, wherein
one of the power-supply leads comprises a first line segment and a second line segment, the first line segment is connected between one of the power-supply lines and the second line segment, the first line segment extends along the first direction, and an acute angle is formed between an extending direction of the second line segment and the first direction;
one of the reference leads comprises a third line segment and a fourth line segment, the third line segment is connected between one of the reference signal lines and the fourth line segment, the third line segment extends along the first direction, and an acute angle is formed between an extending direction of the fourth line segment and the first direction; and
one of the data leads comprises a fifth line segment and a sixth line segment, the fifth line segment is connected between one of the data lines and the sixth line segment, the fifth line segment extends along the first direction, and an acute angle is formed between the extending direction of the sixth line segment and the first direction.

10. The display panel according to claim 8, wherein
the display panel comprises a first edge extending along the first direction; and
among the signal lines connected to a same pixel unit, a distance from at least one of power-supply lines to the first edge is less than a distance from one of the data lines to the first edge;
or a distance from the at least one of the reference signal lines to the first edge is less than a distance from one of the data lines to the first edge.

11. The display panel according to claim 8, wherein
the first sub-pixels, the second sub-pixels, the third sub-pixels and the fourth sub-pixels are alternately arranged in a second direction, and the second direction intersects the first direction; and
one of the first sub-pixels and one of the second sub-pixels that are adjacent to each other in the second direction are connected to the first data line, and one of the third sub-pixel and the fourth sub-pixel adjacent to each other in the second direction are connected to the second data line, wherein the power-supply line or the reference signal line are arranged between one of the first data lines and one of the second data lines that are adjacent to each other.

12. The display panel according to claim 8, wherein
the signal leads connected to a same pixel unit has an arrangement order of: power-supply lead, first data lead, reference lead, second data lead, and power-supply lead; or
the signal leads connected to a same pixel unit has an arrangement order of: reference lead, first data lead, power-supply lead, second data lead, and reference lead.

13. The display panel according to claim 12, wherein
one of the first sub-pixels comprises a first pixel circuit, one of the second sub-pixels comprises a second pixel circuit, one of the third sub-pixels comprises a third pixel circuit, and one of the fourth sub-pixels comprises a fourth pixel circuit;
pixel units are arranged in a pixel unit column in the first direction, the pixel unit column comprises circuit unit columns, one of the circuit unit columns comprises a first pixel circuit column, a second pixel circuit column, a third pixel circuit column, and a fourth pixel circuit column that are sequentially arranged in a second direction, and the second direction intersects the first direction; and the first pixel circuit column comprises first pixel circuits arranged in the first direction, the second pixel circuit column comprises second pixel circuits arranged in the first direction, the third pixel circuit column comprises third pixel circuits arranged in the first direction, and the fourth pixel circuit column comprises fourth pixel circuits arranged in the first direction; and
among the signal lines connected to a same pixel unit column, one of the first data lines is located between the first pixel circuit column and the second pixel circuit column that are adjacent to each other, and one of the second data lines is located between the third pixel circuit column and the fourth pixel circuit column,
wherein one of the reference signal lines is located between the second pixel circuit column and the third pixel circuit column, one of the reference signal lines is connected to four pixel circuit columns in the pixel unit column, one of power-supply lines is located at a side of the first pixel circuit column away from the second pixel circuit column and is connected to the first pixel circuit column and the second pixel circuit column, and another one of power-supply lines is located at a side of the fourth pixel circuit column away from the third pixel circuit column and is connected to the third pixel circuit column and the fourth pixel circuit column; or
wherein one of the power-supply lines is located between the second pixel circuit column and the third pixel circuit column, one of the power-supply lines is connected to four pixel circuit columns in the pixel unit column, one reference signal line is located at a side of the first pixel circuit column away from the second pixel circuit column and is connected to the first pixel circuit column and the second pixel circuit column, and another one of the reference signal lines is located at a side of the fourth pixel circuit column away from the third pixel circuit column and is connected to the third pixel circuit column and the fourth pixel circuit column.

14. The display panel according to claim 8, wherein
the signal leads connected to a same pixel unit have an arrangement order of: power-supply lead, first data lead, reference lead, power-supply lead, second data lead, and reference lead; or
the signal leads connected to a same pixel unit have an arrangement order of: reference lead, first data lead, power-supply lead, reference lead, second data lead, and power-supply lead.

15. The display panel according to claim 14, wherein
one of the first sub-pixels comprises a first pixel circuit, one of the second sub-pixels comprises a second pixel circuit, one of the third sub-pixels comprises a third pixel circuit, and one of the fourth sub-pixels comprises a fourth pixel circuit;
pixel units are arranged as pixel unit columns in the first direction, one of the pixel unit columns comprises circuit unit columns, one of the circuit unit columns comprises a first pixel circuit column, a second pixel circuit column, a third pixel circuit column, and a fourth pixel circuit column that are sequentially arranged in a second direction, and the second direction intersects the first direction; and the first pixel circuit column comprises first pixel circuits arranged in the first direction, the second pixel circuit column comprises second pixel circuits arranged in the first direction, the third pixel circuit column comprises third pixel circuits arranged in the first direction, and the fourth pixel circuit column comprises fourth pixel circuits arranged in the first direction; and
among the signal lines connected to a same pixel unit column, one of the first data lines is located between the first pixel circuit column and the second pixel circuit column that are adjacent to each other, and one of the second data lines is located between the third pixel circuit column and the fourth pixel circuit column,
wherein one of the reference signal lines is located between the second pixel circuit column and the third pixel circuit column and connected to the first pixel circuit column and the second pixel circuit column, another one of the reference signal lines is located at a side of the fourth pixel circuit column away from the third pixel circuit column and connected to the third pixel circuit column and the fourth pixel circuit column, one of the power-supply lines is located at a side of the first pixel circuit column away from the second pixel circuit column and connected to the first pixel circuit column and the second pixel circuit column, and another one of power-supply lines is located between the second pixel circuit column and the third pixel circuit column and connected to the third pixel circuit column and the fourth pixel circuit column; or
wherein one of the power-supply lines is located between the second pixel circuit column and the third pixel circuit column and connected to the first pixel circuit column and the second pixel circuit column, another one of power-supply lines is located at a side of the fourth pixel circuit column away from the third pixel circuit column and connected to the third pixel circuit column and the fourth pixel circuit column, one of the reference signal lines is located at a side of the first pixel circuit column away from the second pixel circuit column and connected to the first pixel circuit column and the second pixel circuit column, and another one of the reference signal lines is located between the second pixel circuit column and the third pixel circuit column and connected to the third pixel circuit column and the fourth pixel circuit column.

16. The display panel according to claim 1, wherein a line width of one of the power-supply leads is greater than a line width of one of the data leads; or
wherein a line width of one of the reference leads is equal to a line width of one of the data leads.

17. The display panel according to claim 1, wherein
a line width of one of the data leads is d1, a line width of one of the power-supply leads is d2, and d1≤d2≤5*d1.

18. The display panel according to claim 1, wherein
the data leads, the power-supply leads, and the reference leads are located in a same layer.

19. The display panel according to claim 1, wherein
the display area comprises power-supply lines and reference signal lines;
one of the power-supply leads comprises a first line segment and a second line segment, the first line segment is connected between one of the power-supply lines and the second line segment, the first line segment extends along the first direction, and an acute angle is formed between an extending direction of the second line segment and the first direction;
one of the reference leads comprises a third line segment and a fourth line segment, the third line segment is connected between one of the reference signal lines and the reference lead, the third line segment extends along the first direction, and the fourth line segment and the second line segment extend in a same direction; and
one of the data leads comprises a fifth line segment and a sixth line segment, the fifth line segment is connected between one of the data lines and the sixth line segment, the fifth line segment extends along the first direction, and the sixth line segment and the second line segment extend in a same direction, wherein a distance between the second line segment and the sixth line segment that are adjacent to each other is D3, and a distance between the fourth line segment and the sixth line segment that are adjacent to each other is D4, where D3<D4.

20. A display apparatus, comprising a display panel, wherein the display panel comprises:
a display area and a non-display area, wherein
the display area comprises sub-pixels and data lines extending along a first direction, the data lines comprise first data lines and second data lines, one of the first data lines is adjacent to one of the second data lines, one of the first data lines is connected to two of the sub-pixels with different colors, and one of the second data lines is connected to two sub-pixels with different colors; and
the non-display area comprises data leads, power-supply leads, and reference leads, the data leads comprise first data leads and second data leads, the first data leads are connected to the first data lines, and the second data leads are connected to the second data lines, wherein one of the power-supply leads and/or one of the reference leads are arranged between one of the first data leads and one of the second data leads that are adjacent to each other.
